(19) United States
(12) Patent Application Publication
(10) Pub. No.: US 2025/0344010 A1
(43) Pub. Date: Nov. 6, 2025

(54) EAR WORN DEVICE AND CASE

(71) Applicant: Masimo Corporation, Irvine, CA (US)

(72) Inventor: Ammar Al-Ali, San Juan Capistrano, CA (US)

(21) Appl. No.: 19/197,701

(22) Filed: May 2, 2025

Related U.S. Application Data
(60) Provisional application No. 63/642,132, filed on May 3, 2024.

(51) Int. Cl. H04R 1/10; H04R 1/02; H05K 5/02; H05K 5/03

(52) U.S. Cl. CPC H04R 1/1041; H04R 1/02; H04R 1/1016; H05K 5/0226; H05K 5/0247; H05K 5/03; H04R 2420/07

(57) ABSTRACT

A system, including: an ear worn device configured to provide audio to a user's ear; a switch configured to receive physical contact from the user and, in response, alter an activation state of the switch; and a case configured to receive the ear worn device when not in use, wherein the case includes an electromagnet configured to magnetically attract the ear worn device, wherein changing the activation state of the switch causes the electromagnet to reduce attraction to the ear worn device to allow the user to more easily remove the ear worn device from the case.

### RELATED APPLICATIONS

The application claims priority to U.S. Provisional Application No. 63/642,132, filed May 3, 2024, entitled “EAR WORN DEVICE AND CASE,” which is hereby incorporated by reference in its entirety.

### BACKGROUND

The present disclosure relates to ear worn devices and their respective cases. Ear worn devices may include earbuds and devices designed to improve the hearing capabilities of a user (typically referred to as “hearing aids”). In general, earbuds and hearing aids include components that are small enough to fit comfortably within the user's ear canal. Earbuds and hearing aids oftentimes have an accompanying case. The case may receive the devices and provide advantageous functions, such as protection from impacts and charging the battery of the earbud or hearing aid. However, conventional cases may provide difficulty to remove the devices from the cases for some users with decreased dexterity in their hand and finger movements. In addition to the small form factor of the earbuds and hearing aids making removal difficult, conventional ear worn devices and their cases may include permanent magnets to restrain movement of the ear worn device to maintain within the case. Overcoming the attraction from the permanent magnets may make gripping and removing the ear worn devices even more difficult for the users with decreased dexterity.

### SUMMARY

In some aspects, the techniques described herein relate to a system, including: an ear worn device configured to provide audio to an ear of a user; a switch configured to receive physical contact from the user and, in response, alter an activation state of the switch; and a case configured to receive the ear worn device when not in use, wherein the case includes an electromagnet configured to magnetically attract the ear worn device, wherein changing the activation state of the switch causes the electromagnet to reduce attraction to the ear worn device to allow the user to more easily remove the ear worn device from the case.

In some aspects, the techniques described herein relate to a system, wherein the switch is a capacitive switch.

In some aspects, the techniques described herein relate to a system, wherein the switch is a mechanical switch.

In some aspects, the techniques described herein relate to a system, wherein the switch is an inductive switch.

In some aspects, the techniques described herein relate to a system, wherein the ear worn device includes the switch.

In some aspects, the techniques described herein relate to a system, wherein the case includes the switch.

In some aspects, the techniques described herein relate to a system, wherein the ear worn device includes a magnet configured to magnetically attract to the electromagnet according to the activation state.

In some aspects, the techniques described herein relate to a system, wherein the case further includes a lid and a main body configured to protect the ear worn device when the ear worn device is restrained within the lid and the main body of the case.

In some aspects, the techniques described herein relate to a system, wherein the lid is hingedly coupled to the main body, wherein a movement by the lid about an axis results in an open position or a closed position of the case.

In some aspects, the techniques described herein relate to a system, wherein the main body includes the electromagnet and a cavity to receive the ear worn device.

In some aspects, the techniques described herein relate to a system, wherein the main body includes a first housing magnet and the lid includes a second housing magnet, wherein the case is in the closed position when a movement by the lid about the axis results in the first housing magnet and the second housing magnet being in a closed position.

In some aspects, the techniques described herein relate to a system, wherein the ear worn device further includes an exterior surface, wherein the switch is positioned along the exterior surface.

In some aspects, the techniques described herein relate to a system, wherein the ear worn device further includes an interior volume, wherein the magnet is positioned within the interior volume.

In some aspects, the techniques described herein relate to a system, wherein the ear worn device is at least one earbud for the user to listen to audio content.

In some aspects, the techniques described herein relate to a system, wherein the ear worn device is at least one hearing device to enhance hearing capabilities of the user.

In some aspects, the techniques described herein relate to a system, including: an ear worn device configured to provide audio to an ear of a user, wherein the ear worn device includes an electromagnet; a switch configured to receive physical contact from the user and, in response, alter an activation state of the switch; and a case configured to receive the ear worn device when not in use, wherein the electromagnet is configured to magnetically attract the ear worn device to the case, wherein changing the activation state of the switch causes the electromagnet to reduce attraction to the ear worn device to allow the user to more easily remove the ear worn device from the case.

In some aspects, the techniques described herein relate to a system, wherein the switch is a capacitive switch.

In some aspects, the techniques described herein relate to a system, wherein the switch is a mechanical switch.

In some aspects, the techniques described herein relate to a system, wherein the switch is an inductive switch.

In some aspects, the techniques described herein relate to a system, wherein the ear worn device includes the switch.

In some aspects, the techniques described herein relate to a system, wherein the case includes the switch.

In some aspects, the techniques described herein relate to a system, wherein the case includes a magnet configured to magnetically attract to the electromagnet according to the activation state.

In some aspects, the techniques described herein relate to a system, wherein the case further includes a lid and a main body configured to protect the ear worn device when the ear worn device is restrained within the lid and the main body of the case.

In some aspects, the techniques described herein relate to a system, wherein the lid is hingedly coupled to the main body, wherein a movement by the lid about an axis results in an open position or a closed position of the case.

In some aspects, the techniques described herein relate to a system, wherein the main body includes the electromagnet and a cavity to receive the ear worn device.

In some aspects, the techniques described herein relate to a system, wherein the main body includes a first housing magnet and the lid includes a second housing magnet, wherein the case is in the closed position when a movement by the lid about the axis results in the first housing magnet and the second housing magnet being in a closed position.

In some aspects, the techniques described herein relate to a system, wherein the ear worn device further includes an exterior surface, wherein the switch is positioned along the exterior surface.

In some aspects, the techniques described herein relate to a system, wherein the ear worn device further includes an interior volume, wherein the magnet is positioned within the interior volume.

In some aspects, the techniques described herein relate to a system, wherein the ear worn device is at least one earbud for the user to listen to audio content.

In some aspects, the techniques described herein relate to a system, wherein the ear worn device is at least one hearing device to enhance hearing capabilities of the user.

In some aspects, the techniques described herein relate to a system, including: an ear worn device configured to receive physical contact from a user, wherein the ear worn device includes: a capacitive switch configured to receive the physical contact from the user and, in response, alter an activation state of the capacitive switch; and a magnet configured to adjust movement of the ear worn device by magnetic coupling in response to the activation state of the capacitive switch; and a case configured to operably couple with the ear worn device, wherein the case includes an electromagnet configured to adjust magnetic attraction to the magnet according to the activation state, wherein changing the activation state of the capacitive switch changes the magnetic attraction of the electromagnet.

In some aspects, the techniques described herein relate to a system, wherein the case further includes a lid and a main body configured to protect the ear worn device when the ear worn device is restrained within the lid and the main body of the case.

In some aspects, the techniques described herein relate to a system, wherein the lid is hingedly coupled to the main body, wherein a movement by the lid about an axis results in an open position or a closed position of the case.

In some aspects, the techniques described herein relate to a system, wherein the main body includes the electromagnet and a cavity to receive the ear worn device.

In some aspects, the techniques described herein relate to a system, wherein the main body includes a first housing magnet and the lid includes a second housing magnet, wherein the case is in the closed position when a movement by the lid about the axis results in the first housing magnet and the second housing magnet being in a closed position.

In some aspects, the techniques described herein relate to a system, wherein when the ear worn device is restrained by the magnet and the electromagnet, the electromagnet is magnetically coupled with the magnet and the activation state is in an active state.

In some aspects, the techniques described herein relate to a system, wherein when the ear worn device is released by the magnet and the electromagnet, the electromagnet is magnetically decoupled with the magnet and the activation state is in an inactive state.

In some aspects, the techniques described herein relate to a system, wherein the ear worn device further includes an exterior surface, wherein the capacitive switch is positioned along the exterior surface.

In some aspects, the techniques described herein relate to a system, wherein the ear worn device further includes an interior volume, wherein the magnet is positioned within the interior volume.

In some aspects, the techniques described herein relate to a system, wherein the ear worn device is at least one earbud for the user to listen to audio content.

In some aspects, the techniques described herein relate to a system, wherein the ear worn device is at least one hearing device to enhance hearing capabilities of the user.

In some aspects, the techniques described herein relate to a system, including: an ear worn device configured to receive physical contact from a user, wherein the ear worn device includes: a capacitive switch configured to receive the physical contact from the user and, in response, alter an activation state of the capacitive switch; and an electromagnet coupled to the capacitive switch and configured to adjust magnetic attraction according to the activation state of the capacitive switch, wherein changing the activation state of the capacitive switch changes the magnetic attraction of the electromagnet; and a case configured to operably couple with the ear worn device, wherein the case includes a magnet configured to adjust movement of the ear worn device by magnetic coupling with the electromagnet according to the activation state.

In some aspects, the techniques described herein relate to a system, wherein the case further includes a lid and a main body configured to protect the ear worn device when the ear worn device is restrained within the lid and the main body of the case.

In some aspects, the techniques described herein relate to a system, wherein the lid is hingedly coupled to the main body, wherein a movement by the lid about an axis results in an open position or a closed position of the case.

In some aspects, the techniques described herein relate to a system, wherein the main body includes the magnet and a cavity to receive the ear worn device.

In some aspects, the techniques described herein relate to a system, wherein the main body includes a first housing magnet and the lid includes a second housing magnet, wherein the case is in the closed position when a movement by the lid about the axis results in the first housing magnet and the second housing magnet being in a closest position.

In some aspects, the techniques described herein relate to a system, wherein when the ear worn device is restrained by the magnet and the electromagnet, the electromagnet is magnetically coupled with the magnet and the activation state is in an active state.

In some aspects, the techniques described herein relate to a system, wherein when the ear worn device is released by the magnet and the electromagnet, the electromagnet is magnetically decoupled with the magnet and the activation state is in an inactive state.

In some aspects, the techniques described herein relate to a system, wherein the ear worn device further includes an exterior surface, wherein the capacitive switch is positioned along the exterior surface.

In some aspects, the techniques described herein relate to a system, wherein the ear worn device further includes an interior volume, wherein the electromagnet is positioned within the interior volume.

In some aspects, the techniques described herein relate to a system, wherein the ear worn device is at least one earbud for the user to listen to audio content.

In some aspects, the techniques described herein relate to a system, wherein the ear worn device is at least one hearing device to enhance hearing capabilities of the user.

In some aspects, the techniques described herein relate to a system, including: a case configured to receive physical contact from a user, wherein the case includes: a capacitive switch configured to receive the physical contact from the user and, in response, alter an activation state of the capacitive switch; and a magnet configured to adjust movement by magnetic coupling in response to the activation state of the capacitive switch; and an ear worn device configured to operably couple with the case, wherein the ear worn device includes an electromagnet configured to adjust magnetic attraction to the magnet according to the activation state, wherein changing the activation state of the capacitive switch changes the magnetic attraction of the electromagnet.

In some aspects, the techniques described herein relate to a system, wherein the case further includes a lid and a main body configured to protect the ear worn device when the ear worn device is restrained within the lid and the main body of the case.

In some aspects, the techniques described herein relate to a system, wherein the lid is hingedly coupled to the main body, wherein a movement by the lid about an axis results in an open position or a closed position of the case.

In some aspects, the techniques described herein relate to a system, wherein the main body includes the magnet and a cavity to receive the ear worn device.

In some aspects, the techniques described herein relate to a system, wherein the main body includes a first housing magnet and the lid includes a second housing magnet, wherein the case is in the closed position when a movement by the lid about the axis results in the first housing magnet and the second housing magnet being in a closest position.

In some aspects, the techniques described herein relate to a system, wherein when the ear worn device is restrained by the magnet and the electromagnet, the electromagnet is magnetically coupled with the magnet and the activation state is in an active state.

In some aspects, the techniques described herein relate to a system, wherein when the ear worn device is released by the magnet and the electromagnet, the electromagnet is magnetically decoupled with the magnet and the activation state is in an inactive state.

In some aspects, the techniques described herein relate to a system, wherein the case further includes an exterior surface, wherein the capacitive switch is positioned along the exterior surface.

In some aspects, the techniques described herein relate to a system, wherein the ear worn device further includes an interior volume, wherein the electromagnet is positioned within the interior volume.

In some aspects, the techniques described herein relate to a system, wherein the ear worn device is at least one earbud for the user to listen to audio content.

In some aspects, the techniques described herein relate to a system, wherein the ear worn device is at least one hearing device to enhance hearing capabilities of the user.

In some aspects, the techniques described herein relate to a system, including: a case configured to receive physical contact from a user, wherein the case includes: a capacitive switch configured to receive the physical contact from the user and, in response, alter an activation state of the capacitive switch; and an electromagnet coupled to the capacitive switch and configured to adjust magnetic attraction according to the activation state of the capacitive switch, wherein changing the activation state of the capacitive switch changes the magnetic attraction of the electromagnet; and an ear worn device configured to operably couple with the ear worn device, wherein the ear worn device includes a magnet configured to adjust movement of the ear worn device by magnetic coupling with the electromagnet according to the activation state.

In some aspects, the techniques described herein relate to a system, wherein the case further includes a lid and a main body configured to protect the ear worn device when the ear worn device is restrained within the lid and the main body of the case.

In some aspects, the techniques described herein relate to a system, wherein the lid is hingedly coupled to the main body, wherein a movement by the lid about an axis results in an open position or a closed position of the case.

In some aspects, the techniques described herein relate to a system, wherein the main body includes the electromagnet and a cavity to receive the ear worn device.

In some aspects, the techniques described herein relate to a system, wherein the main body includes a first housing magnet and the lid includes a second housing magnet, wherein the case is in the closed position when a movement by the lid about a hinge axis results in the first housing magnet and the second housing magnet being in a closest position.

In some aspects, the techniques described herein relate to a system, wherein when the ear worn device is restrained by the magnet and the electromagnet, the electromagnet is magnetically coupled with the magnet and the activation state is in an active state.

In some aspects, the techniques described herein relate to a system, wherein when the ear worn device is released by the magnet and the electromagnet, the electromagnet is magnetically decoupled with the magnet and the activation state is in an inactive state.

In some aspects, the techniques described herein relate to a system, wherein the case further includes an exterior surface, wherein the capacitive switch is positioned along the exterior surface.

In some aspects, the techniques described herein relate to a system, wherein the ear worn device further includes an interior volume, wherein the electromagnet is positioned within the interior volume.

In some aspects, the techniques described herein relate to a system, wherein the ear worn device is at least one earbud for the user to listen to audio content.

In some aspects, the techniques described herein relate to a system, wherein the ear worn device is at least one hearing device to enhance hearing capabilities of the user.

In some aspects, the techniques described herein relate to a system, including: an ear worn device configured to provide audio to an ear of a user; a user input device configured to receive input from the user and, in response, alter an activation state of the user input device; and a case configured to receive the ear worn device when not in use, wherein the case includes an electromagnet configured to magnetically attract the ear worn device, wherein changing the activation state of the user input device causes the electromagnet to reduce attraction to the ear worn device to allow the user to more easily remove the ear worn device from the case.

In some aspects, the techniques described herein relate to a system, including: an ear worn device configured to provide audio to an ear of a user; a user input device configured to receive input from the user and, in response, alter an activation state of the user input device; and a case configured to receive the ear worn device when not in use, wherein the case includes a release configured to restrain the ear worn device, wherein changing the activation state of the user input device causes the release to allow the ear worn device to be more easily removed from the case by the user.

In some aspects, the techniques described herein relate to a system, wherein the release is an electromagnet.

In some aspects, the techniques described herein relate to a system, wherein the release is an electrical switch.

In some aspects, the techniques described herein relate to a system, wherein the release is a mechanical switch.

In some aspects, the techniques described herein relate to a system, wherein the release is an electrical component.

In some aspects, the techniques described herein relate to a system, wherein the electrical component is an electrical switch.

In some aspects, the techniques described herein relate to a system, wherein the electrical component is a sensor.

In some aspects, the techniques described herein relate to a system, wherein the release is a mechanical component.

In some aspects, the techniques described herein relate to a system, wherein the mechanical component is a button.

In some aspects, the techniques described herein relate to a system, wherein the mechanical component is a switch.

In some aspects, the techniques described herein relate to a system, wherein the mechanical component is a lever.

In some aspects, the techniques described herein relate to a system, wherein the mechanical component is a slot holding the ear worn device by friction.

In some aspects, the techniques described herein relate to a system, wherein the mechanical component is a spring release mechanism.

In some aspects, the techniques described herein relate to a system, wherein the mechanical component is a slide release mechanism.

In some aspects, the techniques described herein relate to a system, wherein the mechanical component is a plurality of mechanical latches.

In some aspects, the techniques described herein relate to a system, wherein the mechanical component is a snap-fitting mechanism.

In some aspects, the techniques described herein relate to a system, wherein the release is a change in magnetic polarity.

### BRIEF DESCRIPTION OF THE DRAWINGS

Throughout the drawings, reference numbers may be re-used to indicate correspondence between referenced elements. The drawings are provided to illustrate example embodiments described herein and are not intended to limit the scope of the disclosure.

FIGS. 1A-1B illustrate an ear worn device secured to an ear of a user in accordance with aspects of this disclosure.

FIGS. 2A-2E illustrate perspective views of an ear worn device and a case in accordance with aspects of this disclosure.

FIGS. 3A-3D illustrate block diagrams of certain configurations of an ear worn device and/or a case in accordance with aspects of this disclosure.

FIG. 4 illustrates a routine depicting exemplary operations of an ear worn device and/or a case in accordance with aspects of this disclosure.

FIG. 5 illustrates a block diagram of certain features of an ear worn device and/or a case in accordance with aspects of this disclosure.

FIG. 6 illustrates a perspective view of an ear worn device and a case in accordance with aspects of this disclosure.

### DETAILED DESCRIPTION

Various features and advantages of this disclosure will now be described with reference to the accompanying figures. The following description is merely illustrative in nature and is in no way intended to limit the disclosure, its application, or uses. This disclosure extends beyond the specifically disclosed embodiments and/or uses and obvious modifications and equivalents thereof. Thus, it is intended that the scope of this disclosure should not be limited by any particular embodiments described below. The features of the illustrated embodiments can be modified, combined, removed, and/or substituted as will be apparent to those of ordinary skill in the art upon consideration of the principles disclosed herein.

Traditionally, earbuds are difficult to remove from their case for some users with decreased dexterity in their hands and fingers. Small form factors of the earbuds and cases can cause the process of removing the earbuds to be difficult. For example, an individual with decreased dexterity may find holding the case in one hand to grip the earbud for removal using the other hand challenging. Decreased fine motor skills for an individual suffering with dexterity issues may be unable to grip the earbud from the case. Additionally, conventional earbuds and cases may each include permanent magnets for magnetically attracting one another for restraining movement of the earbuds within the case. The magnets may restrain movement to keep the earbuds immobile, but may provide difficulty to those with decreased fine motor skills. For example, the permanent magnets may restrain the earbuds within the case even when the case is turned upside down. In addition to the small form factor, overcoming the magnetic attraction is another hurdle to make removal of the earbuds even more difficult. Thus, the systems and methods disclosed herein may make removal of the earbuds from the case easier.

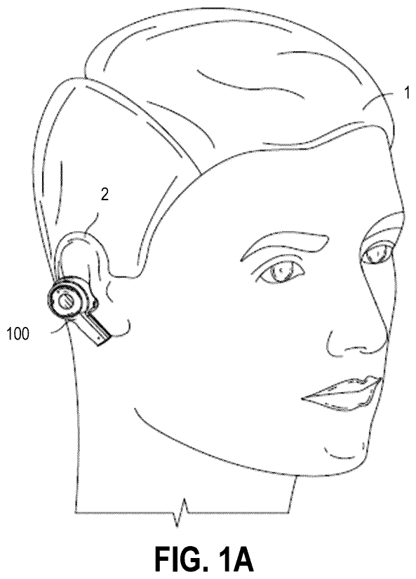

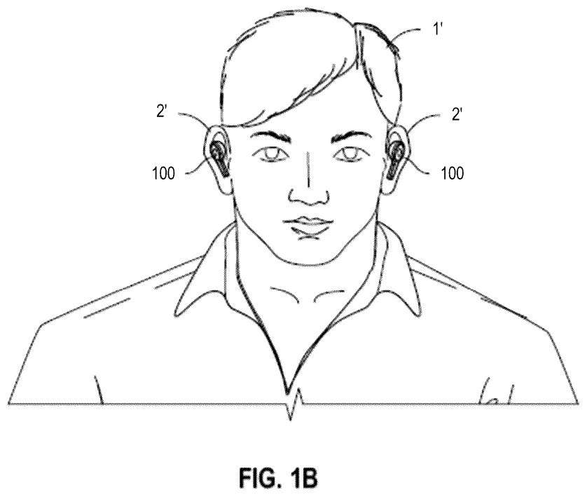

FIGS. 1A-1B illustrate an exemplary use case of an ear worn device secured to an ear of a user in accordance with aspects of this disclosure. FIG. 1A illustrates an ear worn device 100 secured to an ear 2 of a user 1 (which may also be referred to herein as a “subject,” “wearer,” or “patient”). The user 1, in this manner, may have removed the ear worn device 100 from a case and positioned the ear worn device 100 in the ear 2. Removal of the ear worn device 100 from the case may be difficult from some users, such as those users who suffer from lack of dexterity in their hands and fingers. FIG. 1A shows ear worn device 100 secured to the ear 2 in a particular manner, however, such illustrated manner and/or location of securement is not intended to be limiting. FIG. 1B illustrates two ear worn devices 100, one secured to each ear 2′ of a user 1′. Ear worn device 100 can be secured to any of a number of portions and/or locations relative to the ear 2. For example, ear worn device 100 can be secured to, placed adjacent, and/or positioned to be in contact with a pinna, a concha, an ear canal, a tragus, an antitragus, a helix, an antihelix, and/or another portion of the ear 2 (or ear 2′). Ear worn device 100 can be of various structural configurations and/or can include various structural features that can aid mechanical securement to any of such portions of the ear 2 and/or other portions of the user 1 (for example, on or near portions of a head of the user 1).

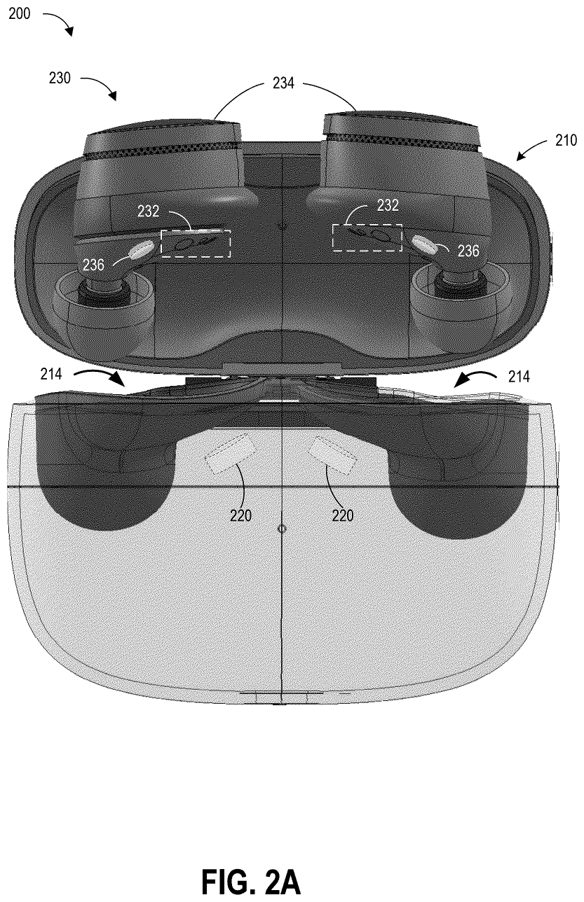

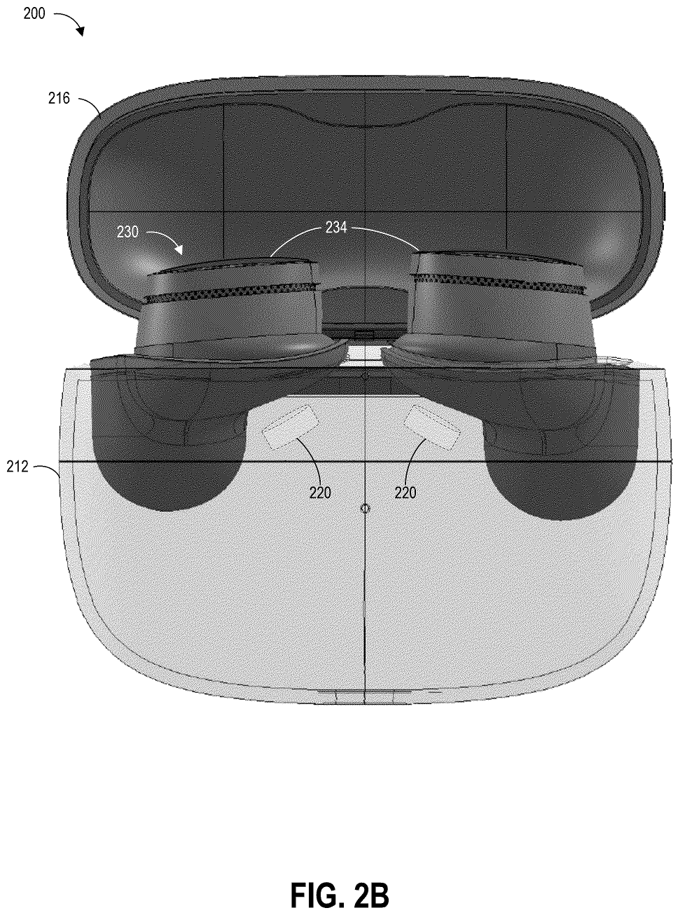

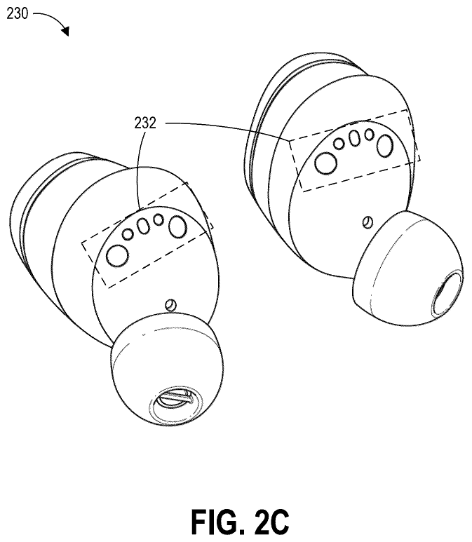

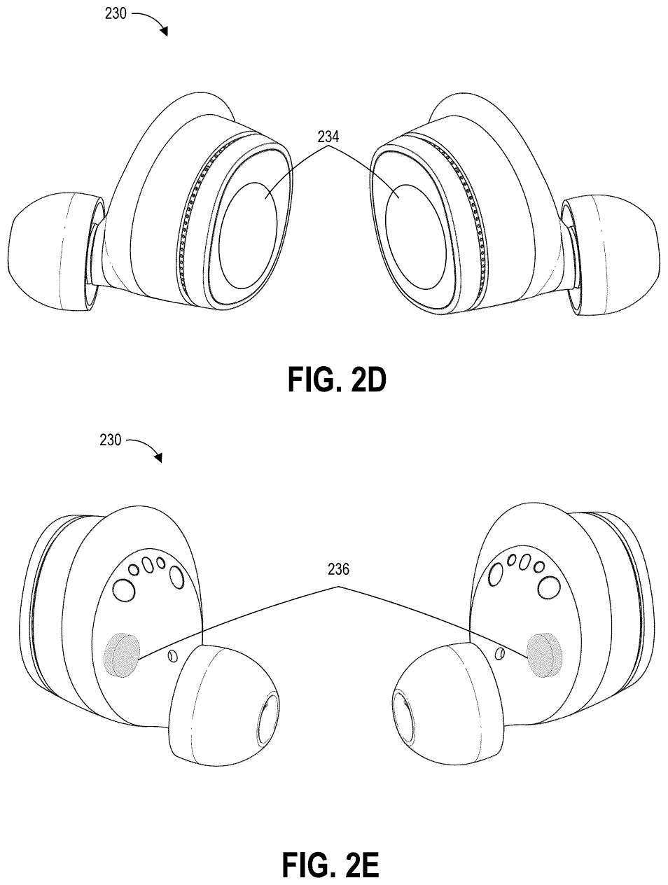

FIGS. 2A-2E illustrate perspective views of the ear worn device and a case in accordance with aspects of this disclosure. FIG. 2A illustrates a system 200 (may also be referred to as a “kit”) including an ear worn device(s) 230 separated from a case 210 in a first configuration (which may also be referred to as a “state”). The first configuration may include the ear worn device(s) 230 separated from the case 210. The first configuration may include the ear worn device(s) 230 being separated from the case 210 when an electromagnetic connection is deactivated. In this manner, the ear worn device(s) 230 may more easily be removed from the case 210 for use by the user. For example, the user may use the ear worn device(s) to listen to music or receive hearing support via the ear worn device(s) 230. In some instances, the first configuration may result from a reversal of polarity of the electromagnet 220 to push the ear worn device(s) 230 out of the case 210. In some examples, the electromagnet 220 may produce a magnetic field of a polarity to attract or repel another magnet (such as magnet 236 of the ear worn device(s) 230). The magnetic attraction may be reversible by actuation from a user input (such as from user input device 234 as disclosed herein). For example, the user may push a button on the case 210 to reverse the polarity of the electromagnet 220. In this manner, reversing the polarity of the magnetic field may generate a repulsive force against the magnet 236, resulting in the magnetic field repelling the ear worn device(s) 230 from the case.

FIG. 2B illustrates the system 200 (may also be referred to as a “kit”) including the ear worn device(s) 230 received by the case 210 in a second configuration. The case 210 may include a main body 212 (may also be referred to as a base) and a lid 216. The main body 212 and the lid 216 may protect the ear worn device(s) 230 when the ear worn device(s) 230 is restrained within the case 210. In some examples, the main body 212 may include a cavity 214 to receive the ear worn device(s) 230. The second configuration may include the ear worn device(s) 230 secured by at least a portion of the case 210, such as within the cavity 214 of the main body 212. In this manner, the second configuration may be when the user stores the ear worn device(s) 230 in the cavity 214 of the main body 212. The ear worn device(s) 230 may be secured to the case 210 when an electromagnetic connection is intact.

In some instances, the cavity 214 may include one or more cavities that are configured to receive a portion of the ear worn device(s) 230. For example, the case 210 may include one or more cavities depending on the number of ear worn devices the case 210 is configured to receive. The cavities may be configured to receive and/or secure a portion or portions of the ear worn device(s) 230.

In some instances, the lid 216 may be positioned in an open position or a closed position. The lid 216 may be in the open position to expose a part of main body 212. In this open position, the lid 216 may allow the user to access the ear worn device(s) 230 (removing the device(s) 230 when the device(s) 230 is received by main body 212) or to store the ear worn device(s) 230 (replacing the device(s) 230 in the cavity 214 when the user stops using the device(s) 230). In some examples, the closed position may place the lid 216 over a top of the main body 212. In the closed position, a portion of the lid 216 may contact the main body 212. The contact between the lid 216 and the main body 212 may occur along an entire perimeter length for each the lid 216 and the main body 212. In this manner, the closed position may enclose a space. In the closed position, the lid 216 and main body 212 may enclose the ear worn device(s) 230 and/or the cavity 214 in the space. In some instances, the lid 216 may be in the open or closed position according to a rotation of the lid 216 with respect to the main body 212 along an axis. The axis may extend along a hinge that interconnects the lid 216 with the main body 212 along the perimeter length for each. The hinge may allow the lid 216 to move relative to main body 212. The rotation along the axis may allow the lid 216 to move from the open position to the closed position (or the closed position to the open position). In the closed position, there is no rotation of the lid 216. The open position may arise in response to the lid 216 rotating from the closed position until the lid 216 reaches a maximum open position. The main body 212 may include a first housing magnet and the lid 216 may include a second housing magnet, each of the housing magnets may be located in a portion of the lid 216 and the main body 212, respectively, opposite of the hinge. When the case 210 is in the closed position the first housing magnet and the second housing magnet may be at a position closest to one another.

In some instances, the case 210 may include an electromagnet 220. The electromagnet 220 may magnetically attract a magnet (such as magnet 236 of the ear worn device(s) 230). The electromagnet 220 may adjust the magnetic attraction according to an activation state of the user input device 234. The activation state may be controlled (activated and deactivated) by input to the user input device 234 as disclosed herein. In an active state, the case 210 may provide a current through a wire in the case 210 that causes the electromagnet 220 to have a magnetic attraction with the magnet 236. In some instances, current flow may be reversed according to the activation state of the user input device 234. For example, when the user input device 234 is in an active state, the current flow may result in magnetic field lines to be in a first orientation. The first orientation may cause an attraction between the electromagnet 220 and the magnet (such as magnet 236 of the ear worn device(s) 230). When the user input device 234 is in an inactive state, the current flow may result in a redirection of the magnetic field lines to be in a second orientation. The second orientation may result in a repulsion between the electromagnet 220 and the magnet (such as magnet 236 of the ear worn device(s) 230) pushing the ear worn device(s) 230 form the case 210. In this manner, the electromagnet 220 may avoid being always engaged, which may result in the case 210 losing battery power rapidly.

In some instances, the electromagnet 220 may mechanically move away from the ear worn device(s) 230, thus reducing magnetic attraction. For example, the case 210 may include a mechanical slider that moves the electromagnet 220. In this manner, the movement of the electromagnet 220 may result in variable distance between the magnet 236 and the electromagnet 220. Increasing the distance between the electromagnet 220 and the magnet 236 may reduce the force of attraction between the magnets. In this manner, moving the electromagnet 220 may decrease difficulty to remove the ear worn device(s) 230 from the case 210.

In some instances, the electromagnet 220 may activate when the lid 216 of the case 210 is opened. For example, the user input device 234 may detect when the lid 216 is in an open position (such as from a change in ambient optical parameters or a change in inductance by a separation of a magnet in the lid 216 and a magnet in the main body 212). In response to the detection of the lid 216 being in an open position, the case 210 may activate the electromagnet 220. In this manner, the electromagnet 220 may magnetically couple to the magnet 236 to restrain movement of the ear worn device(s) 230. In some examples, when the activation state of the user input device 234 changes, the electromagnet 220 may disengage (or in some cases, reverse polarity) allowing for decreased difficulty in removing the ear worn device(s) 230 from the case 210.

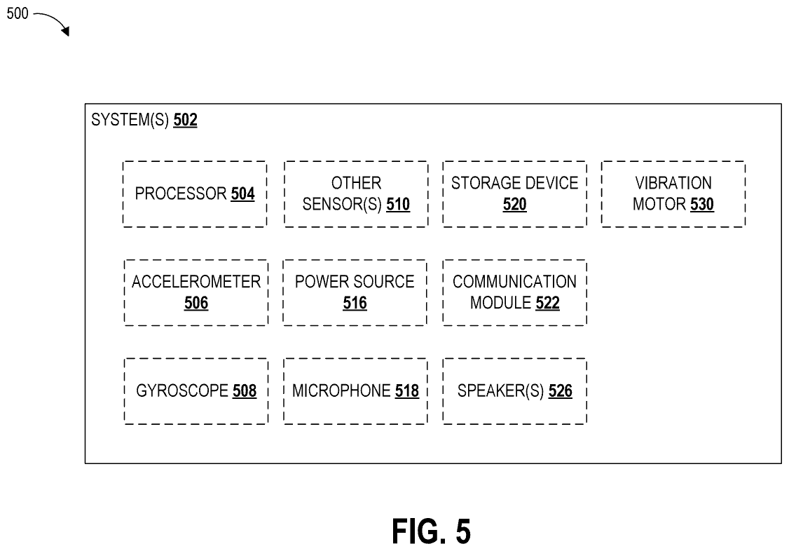

In some cases, the current derives from a battery or another source of electricity, and flows through a wire in contact to, or adjacent to, the electromagnet 220. This creates a magnetic field around the introduced current, magnetizing the electromagnet 220 as if it were a permanent magnet. In some examples, the material used for the electromagnet 220 may also influence the magnetic strength of the electromagnet 220. In some cases, the electromagnet 220 includes a core material. For example, the electromagnet 220 may be made of iron, or another ferromagnetic material. By controlling the current, the case 210 may control the electromagnet 220 to be active or inactive, which corresponds to an increased or reduced attraction. When the current is turned off, the electromagnet 220 loses its magnetism. In some examples, the main body 212 may include an interior volume, such that the electromagnet 220 is located in the interior volume. In some examples, part of the electromagnet 220 may be located on an exterior surface of the main body 212. The electromagnet 220 may be of permanent (or controllable) polarity. In some examples, the electromagnet 220 may be coupled to an electrical device included in the main body 212. In this manner, the electromagnet 220 may be controllable according to an instruction from the electrical device. The instruction may be associated with an input by the user. In some examples, the electrical device may include a controller (such as the processor 504 in FIG. 5). In some instances, the electromagnet 220 may include predetermined dimensions. In some instances, the predetermined dimensions may include two-dimensional (2D) or three-dimensional (3D) magnet of varying shapes. For example, the electromagnet 220 may be circular, elliptical, polygonal (including square, rectangular, triangular, hexagonal, etc.), cylindrical, a rectangular prism, a triangular prism, spherical, or another geometry applicable for positioning the electromagnet 220 with respect to the main body 212 (or other component of the system 200). In some examples, the predetermined dimensions may include a length, width, and thickness. The length, width, and thickness may each individually (and independently) be within a range such as 0.0-1.0 mm, 1.0-5.0 mm, 5.0-10.0 mm, 10.0-20.0 mm, 20.0-50.0 mm, 0.0-5.0 mm, 0.0-10.0 mm, 0.0-20.0 mm, 0.0-50.0 mm, or another value within the ranges disclosed herein. In some examples, the electromagnet 220 may be positioned within the main body 212. In some examples, at least a portion of the electromagnet 220 may be positioned along an exterior surface of the main body 212. The electromagnet 220 may include various materials. In some examples, the electromagnet 220 may include metallic materials with conductive properties. For example, the electromagnet 220 may be made of iron (or ferrite), boron, neodymium (including nickel-plated neodymium), and/or alloys of a combination of the metallic materials. The electromagnet 220 may include neodymium of grades N28 to N52 (including N42). In some examples, the case 210 may include more than one electromagnet, thus the properties disclosed herein regarding the electromagnet 220 may be applicable to a plurality of electromagnets.

The ear worn device(s) 230 may be removable from the case 210 to be positioned in the user's ear. In some instances, the ear worn device(s) 230 may provide audio to the user's ear. The ear worn device(s) 230 may provide audio content to the user and/or enhance hearing capabilities of the user. In some examples, the ear worn device(s) 230 may be one or more earbud, headphone, hearing device (such as a hearing aid), sound suppressing device (such as ear muffs and/or ear plugs), and/or any combination of the foregoing or another ear worn device applicable to the disclosure herein. In some examples, the ear worn device(s) 230 may be difficult for some users to remove from the case 210 due to decreased dexterity capabilities of the user. In some examples, the ear worn device(s) 230 may include the electrical contacts 232, the user input device 234, and the magnet 236. As disclosed herein, the user may instruct the electromagnet 220 to reduce magnetic attraction and allow the user to remove the ear worn device(s) 230 from the case 210. In this manner, the ear worn device(s) 230 is removable without the user having to grip the ear worn device(s) 230 and pull the ear worn device(s) 230 from the case 210 to overcome a magnetic attraction, which may be restrictive to some users. In some instances, the case 210 may include a button to release the electromagnet 220 (such as the user input device 234 as disclosed herein). By releasing the electromagnet 220, the user may remove the ear worn device(s) 230 from the case 210 by turning the case 210 upside down so the ear worn device(s) 230 can fall out of the case 210. The case 210 may include the button on an internal portion or an external portion of the main body 212 or the lid 216.

The ear worn device(s) 230 may include electrical contacts 232. The electrical contacts 232 may be positioned at some part of the ear worn device(s) 230. For example, the electrical contacts 232 may be positioned on a main body (for example, a portion of the main body in FIG. 2C). The portion may be a front surface of the ear worn device(s) 230. In some examples, the portion may be on other parts of the ear worn device(s) 230. In some instances, the electrical contacts 232 may interface between the ear worn device(s) 230 and the case 210. The electrical contacts 232 may provide instructions from the ear worn device(s) 230 to the case 210. In this manner, the ear worn device(s) 230 may provide instructions to the case 210 to activate (or deactivate) an electromagnet. For example, the ear worn device(s) 230 may receive an input from the user, such as physical contact, on the user input device 234. In response to the contact, the ear worn device(s) 230 may generate an electrical signal and transmit the electrical signal, which may instruct the electromagnet 220 to deactivate such that the ear worn device(s) 230 may be removable from the case 210. The instruction to the case 210 may include an instruction for the electromagnet 220 to reduce attraction to a magnet (such as magnet 236 of the ear worn device(s) 230).

In some instances, the ear worn device(s) 230 may include a user input device 234. The user input device 234 may include a switch, button, sliding mechanism, sensor, actuator, and/or another component the user may interact with for the applications disclosed herein. In some examples, the ear worn device(s) 230 may include an exterior surface, such that the user input device 234 is located on the exterior surface.

In some cases, the user input device 234 may include a switch to receive contact by the user, such as a capacitive switch. The capacitive switch may include a touch-sensitive interface to receive the contact from the user. For example, the capacitive switch may include a touchpad, capacitive sensor, a circuit, and a controller. In some cases, the capacitive switch may be a surface capacitive switch or a projected capacitive switch. The surface capacitive switch may measure the capacitance change at corners of the capacitive sensor, and a touch position is computed from a change in capacitance measured at the capacitive sensor. The projected capacitive switch may operate by creating an electrostatic field over the capacitive sensor, such that when the field is disturbed by a conductive object, such as the user's finger, the capacitive sensor detects the change and calculates the touch position. In some cases, the capacitive switch may operate including an activation state. The activation state may include an active state and an inactive state. The activation state may correspond to a change in capacitance, such as the contact by the user. For example, when there is no contact by the user and the ear worn device(s) 230 is received by the case 210, the activation state may be in an active state. In this manner, the active state of the capacitive switch may provide instruction to the electromagnet 220 to attract the magnet 236 to restrain movement of the ear worn device(s) 230 received by the case 210. When there is contact by the user and the ear worn device(s) 230 is received by the case 210, the activation state may adjust to an inactive state. In this manner, the inactive state of the capacitive switch may provide instruction to the electromagnet 220 to reduce attraction to the magnet 236 to allow easier movement of the ear worn device(s) 230 from the case 210. When there is (or is not) contact by the user and the ear worn device(s) 230 is not received by the case 210, the activation state may adjust, but may have no effect with respect to the coupling of the electromagnet 220 and the magnet 236. However, the activation state may change regardless of the ear worn device(s) 230 being received by the case 210. In this manner, the contact may provide other uses to the ear worn device(s) 230, such as adjusting a volume of audio played by the ear worn device(s) 230, a power setting of the ear worn device(s) 230 and/or a pairing function between the ear worn device(s) 230 and the case 210. For example, if the capacitive switch is on the ear worn device(s) 230, an active state provides power to the ear worn device(s) 230 and an inactive state powers off the ear worn device(s) 230. In some examples, the capacitive switch may be included in the ear worn device(s) 230 or the case 210.

In some cases, the user input device 234 may include a sensor to receive input by the user, such as an infrared sensor. The infrared sensor may include an interface to obtain infrared radiation from the user (and the surrounding environment). The infrared sensor may be active, passive, or thermal. The active infrared sensor may include a light emitting diode (LED) and a receiver, such that when an object (for example, the user's hand) comes close to the sensor, the infrared light from the LED reflects off of the object and is detected by the receiver. In this manner, the active infrared sensors may act as a proximity sensor. The LEDs may operate in the infrared wavelength, for example, 700-1000 nanometers (nm). The passive infrared sensors may detect infrared radiation and do not emit infrared radiation from an LED. In some examples, passive infrared sensor may include at least one strip of pyroelectric material, an infrared filter (to block out all other wavelengths of light), a Fresnel lens (to collect light from many angles into a single point), and a housing unit (to protect the sensor from other environmental variables, such as humidity). The thermal infrared sensor may detect infrared radiation from an object to measure temperature. In some cases, the infrared sensor may control an activation state of the electromagnet 220 and the magnet 236. The activation state may provide the same functionality as disclosed herein for the capacitive switch. In some examples, the infrared sensor may alter the activation state according to a change in infrared activity (or temperature). For example, the user may bring their hand close to a location of where the infrared sensor may be located, changing the infrared activity. In this manner, the infrared sensor may alter an activation state according to the action by the user. In some examples, the infrared sensor may be included in the ear worn device or the case.

In some cases, the user input device 234 may include a sensor to receive input by the user, such as an inductive sensor. The inductive sensor may include an interface to receive the input from the user. In some examples, the input may include physical contact, such as the user pressing the interface. The inductive sensor may include a non-conductive rigid surface, conductive target, spacer(s), and or a sensor. The inductive sensor may be structured such that the physical contact by the user may displace the non-conductive surface and register a change in inductance. In some cases, the inductive sensor may control an activation state of the electromagnet 220 and a magnet 236. The activation state may include the same functionality as disclosed herein for the capacitive switch. In some cases, the inductive sensor may alter the activation state according to a change in inductive measurements. In some examples, the inductive sensor may be included in the ear worn device(s) 230 and/or the case 210. In some cases, the lid 216 and the main body 212 each may include a magnet, a first housing magnet and a second housing magnet, respectively. When the lid 216 of the case 210 opens and the first housing magnet in the lid 216 moves around the ear worn device(s) 230, the inductance may change. In response to the change in inductance, the ear worn device(s) 230 may associate the change in inductance to the lid 216 being opened. In this manner, the ear worn device(s) 230 may transmit a signal to change the activation state to deactivate the electromagnet 220.

In some cases, the user input device 234 may include a switch to receive an input by the user, such as an electrical switch. The electrical switch may include an interface for controlling a flow of electricity in response to the input by the user. In some examples, the electrical switch may include various types of switches. For example, the electrical switch may include a transistor switch (including MOSFET and IGBT), diode (and triode) switch, or another type of electrical switch applicable to the systems and devices disclosed herein. The electrical switch may control the flow of electricity according to a state of the switch. The electrical switch may include two states, on and off. In some cases, the electrical switch may control an activation state of the electromagnet 220 and the magnet 236. The activation state may include the same functionality as disclosed herein for the capacitive switch. In some cases, the electrical switch may alter the activation state according to a change in electrical activity. The change in electrical activity may correspond with the contact by the user. For example, when the user contacts the electrical switch the resistance may change, which may cause the electrical switch to change the activation state. In some examples, the electrical switch may be included in the ear worn device(s) 230 and/or the case 210.

In some cases, the user input device 234 may include a switch to receive contact by the user, such as a mechanical switch. The mechanical switch may include an interface for controlling a flow of electricity in response to the contact by the user. In some examples, the mechanical switch may include various types of switches. For example, the mechanical switch may include a toggle switch, push-button switch, rotary switch, magnetic reed switch, DIP switches, or another type of mechanical switch applicable to the systems and devices disclosed herein. The mechanical switch may control the flow of electricity according to a position of the switch. The mechanical switch may include two states, on and off. In some cases, the mechanical switch may control an activation state of the electromagnet 220 and the magnet 236. The activation state may include the same functionality as disclosed herein for the capacitive switch. In some cases, the mechanical switch may alter the activation state according to a change in position of the mechanical switch. The change in the position may correspond with the contact by the user. For example, when the user contacts the mechanical switch the position of the switch may change, which may cause the mechanical switch to change the activation state. In some examples, the mechanical switch may be included in the ear worn device(s) 230 and/or the case 210.

In some cases, the user input device 234 may include a button to receive contact by the user, such as a mechanical ejector. In some examples, the mechanical ejector may include a release button. The release button may interact with a spring mechanism. In some cases, the release button may directly impinge upon a mechanical device that extends into the ear worn device. In some examples, the mechanical ejector may be hinged so that pressing the release button in an upward direction causes portions of the mechanical ejector in a downward direction. In this manner, if an ear worn device(s) 230 is within the associated slot, the mechanical ejector may push the ear worn device(s) 230 at least partially out of the slot. The user may then manually remove the ear worn device(s) 230 from the case 210. In some cases, the mechanical ejector may control an activation state of the electromagnet 220 and the magnet 236. The activation state may provide the same functionality as disclosed herein for the capacitive switch. In some examples, the mechanical ejector may be included in the ear worn device(s) 230 and/or the case 210.

In some cases, the user input device 234 may include a sliding mechanism to receive contact by the user. In some cases, the sliding mechanism may include a mechanical slider, a capacitive sliding mechanism, or another type of component to receive a sliding action by the user. In some cases, the sliding mechanism may control an activation state of the electromagnet 220 and the magnet 236. The activation state may provide the same functionality as disclosed herein for the capacitive switch. The sliding mechanism may include release sliders. The release sliders may function mechanically, capacitively, electrically, electromagnetically (or another sensor approach as disclosed herein) to secure and release the ear worn device(s) 230. For example, the release sliders may move downwardly, such that the release sliders may engage the ear worn device(s) 230, urging the ear worn device(s) 230 at least partially out from the cavity 214 to be accessible and removable by the user. In some examples, the release slider may be configured such that downward movement may cause the magnet 236 in the ear worn device(s) 230 and the electromagnet 220 to reduce attraction from one another. In this manner, the ear worn device(s) 230 may be removed from the cavity 214 of the case 210 without having to overcome a magnetic attraction. In some examples, the release sliders may be provided for a plurality of ear worn devices to permit removal of the ear worn devices independent of one another. In other embodiments, a single release slider may be used to urge the plurality of ear worn devices out of their respective slots. In some examples, the mechanical slider may be included in the ear worn device(s) 230 or the case 210.

In some cases, the user input device 234 may include a sensor to receive input by the user, such as an optical sensor. The optical sensor may include an interface to detect and convert incident light rays into electrical signals. In some cases, the optical sensor may include an ambient light sensor. The ambient light sensor may include reflective photosensors and/or a photoconductive device. The reflective photosensors may detect the motion of objects by measuring the reflection of light across them. The photoconductive devices may become electrically conductive by absorbing incident light rays. The ambient light sensor may control an activation state of the electromagnet 220 and the magnet 236. The activation state may provide the same functionality as disclosed herein for the capacitive switch. In some cases, the ambient light sensor may be located within the case 210. In some examples, when the case 210 opens, a change in light received by the ambient light sensor may change the activation state. In some examples, the optical sensor may be included in the ear worn device or the case.

In some examples, the ear worn device(s) 230 may include a magnet 236 that may be magnetically coupled to an electromagnet 220 housed within the main body 212. The magnet 236 may cause the ear worn device(s) 230 to remain in a first position, such that the ear worn device(s) 230 remains stationary until the electromagnet 220 is deactivated. In some examples, the ear worn device(s) 230 may include an interior volume, such that the magnet 236 is located in the interior volume. In some examples, the magnet 236 may be located on the exterior surface of the ear worn device(s) 230. The magnet 236 may be of permanent (or controllable) polarity. The magnet 236 may include predetermined dimensions. In some instances, the predetermined dimensions may include two-dimensional (2D) or three-dimensional (3D) magnet of varying shapes. For example, the magnet 236 may be circular, elliptical, polygonal (including square, rectangular, triangular, hexagonal, etc.), cylindrical, a rectangular prism, a triangular prism, spherical, or another geometry applicable for positioning the magnet 236 with respect to the ear worn device(s) 230 (or other component in system 200). In some examples, the predetermined dimensions may include a length, width, and thickness. The length, width, and thickness may each individually (and independently) be within a range such as 0.0-1.0 mm, 1.0-5.0 mm, 5.0-10.0 mm, 10.0-20.0 mm, 20.0-50.0 mm, 0.0-5.0 mm, 0.0-10.0 mm, 0.0-20.0 mm, 0.0-50.0 mm, or another value within the ranges disclosed herein. In some examples, the magnet 236 may be positioned within the ear worn device(s) 230. In some examples, at least a portion of the magnet 236 may be positioned along the exterior surface of the ear worn device(s) 230. The magnet 236 may include various materials. In some examples, the magnet 236 may include metallic materials with conductive properties. For example, the magnet 236 may be made of iron (or ferrite), boron, neodymium (including nickel-plated neodymium), and/or alloys of a combination of the metallic materials. The magnet 236 may include neodymium of grades N28 to N52 (including N42). In some examples, the ear worn device(s) 230 includes more than one magnet, thus the properties disclosed herein regarding the magnet 236 may be applicable to a plurality of magnets.

In some examples, the ear worn device(s) 230 may be released from the case 210 in response to the user input device 234 receiving an instruction from the user. The instruction from the user may include physical motion, voice activation, acceleration changes, gyroscopic position, geolocation, or another form of instructing the release of the ear worn device(s) 230.

In some examples, the ear worn device(s) 230 (and/or the case) may include voice activation to release the ear worn device(s) 230. For example, the ear worn device(s) 230 (and/or the case) may include a microphone (such as microphone 518 in FIG. 5) to receive external audio, such as the user's voice instruction. In response to receiving the voice instruction, the user input device 234 may instruct for the electromagnet 220 to deactivate.

In some examples, the ear worn device(s) 230 (and/or the case 210) may include an accelerometer and/or a gyroscope (such as accelerometer 506 and gyroscope 508 in FIG. 5). In this manner, the position of the ear worn device(s) 230 (and/or the case 210) may cause the ear worn device(s) 230 to be released from the case. For example, turning the ear worn device(s) 230 (and/or the case) upside down while the lid is open and shaking may cause a change in acceleration and/or orientation, which may be received by the user input device 234 as an instruction to release the ear worn device(s) 230 from the case 210. In response, the user input device 234 may instruct the electromagnet 220 to deactivate (and alternatively, turning the ear worn device(s) 230 and/or case 210 another direction may reset the electromagnet 220).

In some examples, the ear worn device(s) 230 (and/or the case) may include a process and components for identifying a geolocation. For example, receiving geolocation information from a mobile communication device, wireless router, cell tower, or another component to transmit location information. In another example, the ear worn device(s) 230 (and/or case 210) may include a geolocation module (such as an inertial measurement unit (IMU) as discussed in FIG. 5) to identify the location of the ear worn device(s) 230 (and/or the case 210) independent from another device. In some examples, the ear worn device(s) 230 (and/or case 210) may cause the ear worn device(s) 230 to be released from the case at a known location or when proximate to other devices. For example, the known location may be at the user's home, in the user's car, at a library, etc. In some examples, the proximity to other devices may include the ear worn device(s) 230 being within a distance to the user's mobile communication device and/or another connected device. The distance may correspond to physical limits associated with some radio frequency (RF) signal coverage, such as telecommunication protocols including Bluetooth Low Energy (BLE), WiFi, 4G, 5G, or another telecommunication protocol applicable to the aspects disclosed herein.

In some examples, the ear worn device(s) 230 (and/or case) may control a reactivation of an attachment between the ear worn device(s) 230 and the case 210. For example, the ear worn device(s) 230 may receive instruction to reactivate an attraction between magnet 236 and the electromagnet 220. In some examples, the ear worn device(s) 230 (and/or case 210) may control reactivation of the attraction without mechanically moving components of the user input device 234. Rather, the user may reactivate the attraction by engaging the user input device 234. For example, the ear worn device(s) 230 (or the case 210) may receive physical contact from the user on the user input device 234, such that the user input device 234 transmits the instruction to the case 210 to reactivate the electromagnet 220.

In some instances, the ear worn device(s) 230 may be released from main body 212 of the case 210. For example, the magnetic coupling between the magnet 236 and the electromagnet 220 may reduce attraction (and thus decouple) allowing the user to obtain the ear worn device(s) 230 from the case 210. In some examples, the electromagnetic coupling between the ear worn device(s) 230 and the case 210 is deactivated without moving the ear worn device(s) 230 relative to the case 210 (or relative to one another). In this manner, the ear worn device(s) 230 may be removable from the case 210 without a mechanical ejection and/or a magnetic repulsion. In some examples, the release of the ear worn device(s) 230 from the case 210 may be with movement. For example, the release of the ear worn device(s) 230 may include electromagnetic changes and/or mechanical ejection. In some examples, the ear worn device (and/or the case) may include a mechanical ejector. The mechanical ejector may include the mechanical button, switch, and/or sliding mechanism as disclosed herein. The electromagnetic changes may include changes in polarity of the magnet 236 and/or electromagnet 220 causing a repulsive force between the ear worn device(s) 230 and the case 210.

FIGS. 2C-2E illustrate perspective views of the ear worn device(s) 230 in accordance with aspects of this disclosure. FIG. 2C illustrates a perspective view of the ear worn device(s) 230 from a front view, including a view of the electrical contacts 232. FIG. 2D illustrates a perspective view of the ear worn device(s) 230 from a rear view, including the user input device 234. FIG. 2E illustrates a perspective view of the ear worn device(s) 230 from a side view, including the magnet 236.

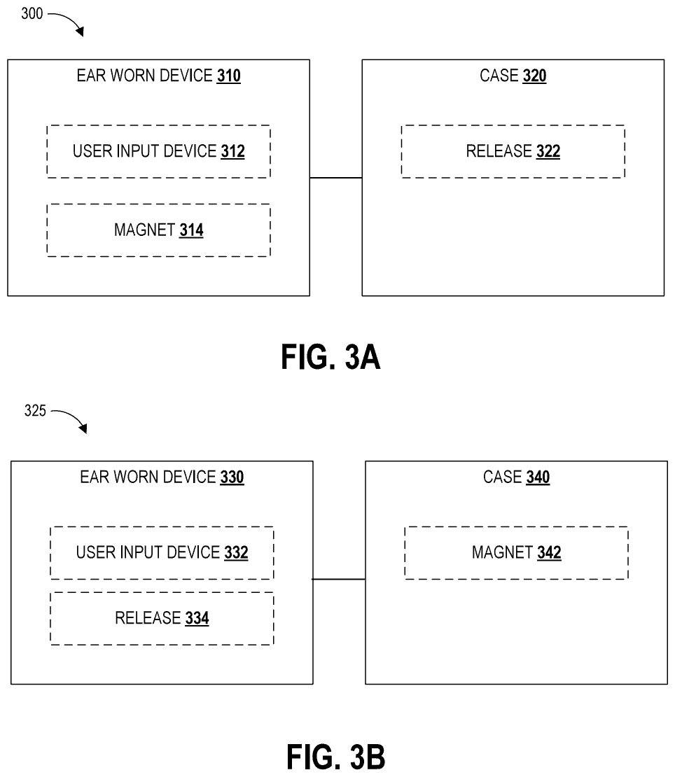

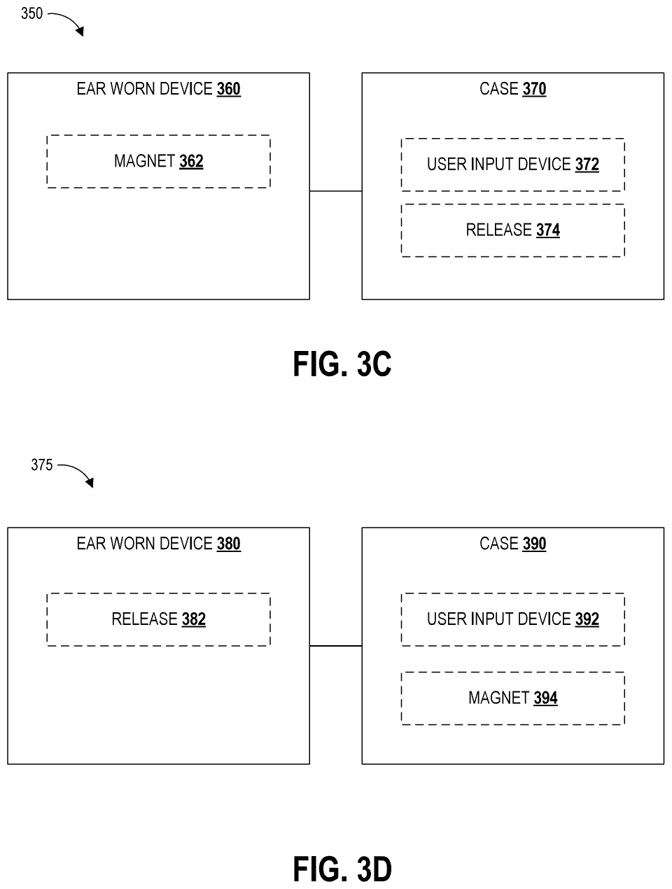

FIGS. 3A-3D illustrate block diagrams of various embodiments of systems in accordance with aspects of this disclosure. In some instances, the systems may include the aspects as disclosed herein (such as the system 200 disclosed in FIGS. 2A-2E). Thus, the components disclosed herein may be incorporated into the variety of system embodiments of FIGS. 3A-3D.

As illustrated in FIG. 3A, a system 300 may include an ear worn device 310 and case 320 in a first configuration (may also referred to as “states”). In the first configuration, the ear worn device 310 may include a user input device 312 and a magnet 314 and the case 320 may include a release 322. The first configuration may include the ear worn device 310 received by the case 320 (in a manner as disclosed herein). The ear worn device 310 may receive a user input via the user input device 312. The ear worn device 310 may generate an instruction in response to receiving the user input. The ear worn device 310 may transmit the instruction to the case 320. In some examples, the instruction transmitted may be communicated via electrical contacts (such as electrical contacts 232 in FIGS. 2A-2E). The electrical contacts may interface with corresponding contacts associated with the case 320. In some examples, the instruction may be transmitted over-the-air or without contact between the ear worn device 310 and the case 320. The case 320 may alter an activation state of the release 322 in response to receiving the instruction from the ear worn device 310. The release 322 may include an electrical component (such as an electromagnet, electrical switch, sensor, or another type as disclosed herein), a mechanical component (such as button, switch, lever, slot holding the ear worn device 310 by friction, a spring release mechanism, slide release mechanism, mechanical latches, snap-fitting mechanisms, or another type as disclosed herein), a change in magnetic polarity, or another component used to restrain movement of the ear worn device 310. The activation state may include an active state and an inactive state. In some examples, a default of the activation state is the active state when the ear worn device 310 is received by the case 320. In some examples, when the ear worn device 310 is received by the case 320 and the release 322 is an electromagnet, the release 322 is active such that the magnet 314 and the release 322 are magnetically attracted to the other. The user may provide the input to the user input device 312 to alter the activation state. In response, the case 320 may change the activation state from the active state to the inactive state. The inactive state may deactivate the release 322. In this manner, when the ear worn device 310 is received by the case 320, the release 322 is inactive such that the magnet 314 and the release 322 have reduced magnetic attraction to the other. The user may be able to remove the ear worn device 310 from the case 320 without having to grip and pull the ear worn device 310 to overcome a magnetic attraction. In some examples, the ear worn device 310 remains in the case 320 and the user may provide a reactivation input to the user input device 312 to alter the activation state. In response, the case 320 may change the activation state from the inactive state to the active state. The active state may activate the release 322 again. In this manner, when the ear worn device 310 is received by the case 320, the release 322 is active such that the magnet 314 and the release 322 are magnetically attracted to the other, as described herein, and the ear worn device 310 remains attached to the case 320. In some instances, the ear worn device 310 may receive the reactivation input without being removed from the case 320 or mechanically re-engaging an ejection mechanism.

As illustrated in FIG. 3B, a system 325 may include an ear worn device 330 and case 340 in a second configuration (may also referred to as “states”). In the second configuration, the ear worn device 330 may include a user input device 332 and a release 334 and the case 340 may include a magnet 342. The second configuration may include the ear worn device 330 received by the case 340 (in a manner as disclosed herein). The ear worn device 330 may receive a user input via the user input device 332. The ear worn device 330 may generate an instruction in response to receiving the user input. The ear worn device 330 may alter an activation state of the release 334 in response to receiving the instruction. The release 334 may include an electrical component (such as an electromagnet, electrical switch, sensor, or another type as disclosed herein), a mechanical component (such as button, switch, lever, slot holding the ear worn device 330 by friction, a spring release mechanism, slide release mechanism, mechanical latches, snap-fitting mechanisms, or another type as disclosed herein), a change in magnetic polarity, or another component used to restrain movement of the ear worn device 330. The activation state may include an active state and an inactive state. In some examples, a default of the activation state is the active state when the ear worn device 330 is received by the case 340. In some examples, when the ear worn device 330 is received by the case 340 and the release 334 is an electromagnet, the release 334 is active such that the magnet 342 and the release 334 are magnetically attracted to the other. The user may provide the input to the user input device 332 to alter the activation state. In response, the ear worn device 330 may change the activation state from the active state to the inactive state. The inactive state may deactivate the release 334. In this manner, when the ear worn device 330 is received by the case 340, the release 334 is inactive such that the magnet 342 and the release 334 have reduced magnetic attraction to the other. The user may be able to remove the ear worn device 330 from the case 340 without having to grip and pull the ear worn device 330 to overcome a magnetic attraction. In some examples, the ear worn device 330 remains in the case 340 and the user may provide a reactivation input to the user input device 332 to alter the activation state. In response, the ear worn device 330 may change the activation state from the inactive state to the active state. The active state may activate the release 334 again. In this manner, when the ear worn device 330 is received by the case 340, the release 334 is active such that the magnet 342 and the release 334 are magnetically attracted to the other, as described herein, and the ear worn device 330 remains attached to the case 340. In some instances, the ear worn device 330 may receive the reactivation input without being removed from the case 340 or mechanically re-engaging an ejection mechanism.

As illustrated in FIG. 3C, the system 350 may include an ear worn device 360 and case 370 in a third configuration (may also referred to as “states”). In the third configuration, the ear worn device 360 may include a magnet 362 and the case 370 may include a user input device 372 and a release 374. The third configuration may include the ear worn device 360 received by the case 370 (in a manner as disclosed herein). The case 370 may receive a user input via the user input device 372. The case 370 may generate an instruction in response to receiving the user input. The case 370 may alter an activation state of the release 374 in response to receiving the instruction. The release 374 may include an electrical component (such as an electromagnet, electrical switch, sensor, or another type as disclosed herein), a mechanical component (such as button, switch, lever, slot holding the ear worn device 360 by friction, a spring release mechanism, slide release mechanism, mechanical latches, snap-fitting mechanisms, or another type as disclosed herein), a change in magnetic polarity, or another component used to restrain movement of the ear worn device 360. The activation state may include an active state and an inactive state. In some examples, a default of the activation state is the active state when the ear worn device 360 is received by the case 370. In some examples, when the ear worn device 360 is received by the case 370 and the release 374 is an electromagnet, the release 374 is active such that the magnet 362 and the release 374 are magnetically attracted to the other. The user may provide the input to the user input device 372 to alter the activation state. In response, the case 370 may change the activation state from the active state to the inactive state. The inactive state may deactivate the release 374. In this manner, when the ear worn device 360 is received by the case 370, the release 374 is inactive such that the magnet 362 and the release 374 have reduced magnetic attraction to the other. The user may be able to remove the ear worn device 360 from the case 370 without having to grip and pull the ear worn device 360 to overcome a magnetic attraction. In some examples, the ear worn device 360 remains in the case 370 and the user may provide a reactivation input to the user input device 372 to alter the activation state. In response, the case 370 may change the activation state from the inactive state to the active state. The active state may activate the release 374 again. In this manner, when the ear worn device 360 is received by the case 370, the release 374 is active such that the magnet 362 and the release 374 are magnetically attracted to the other, as described herein, and the ear worn device 360 remains attached to the case 370. In some instances, the case 370 may receive the reactivation input without having the ear worn device 360 removed from the case 370 or mechanically re-engaging an ejection mechanism.

As illustrated in FIG. 3D, the system 375 may include an ear worn device 380 and case 390 in a fourth configuration (may also referred to as “states”). In the fourth configuration, the ear worn device 380 may include a release 382 and the case 390 may include a user input device 392 and a magnet 394. The fourth configuration may include the ear worn device 380 received by the case 390 (in a manner as disclosed herein). The case 390 may receive a user input via the user input device 392. The case 390 may generate an instruction in response to receiving the user input. The case 390 may transmit the instruction to the ear worn device 380. In some examples, the instruction transmitted may be communicated via electrical contacts (such as electrical contacts 232 in FIGS. 2A-2E). The electrical contacts on the ear worn device 380 may interface with corresponding contacts associated with the case 390. In some examples, the instruction may be transmitted over-the-air or without contact between the ear worn device 380 and the case 390. The ear worn device 380 may alter an activation state of the release 382 in response to receiving the instruction from the case 390. The release 382 may include an electrical component (such as an electromagnet, electrical switch, sensor, or another type as disclosed herein), a mechanical component (such as button, switch, lever, slot holding the ear worn device 380 by friction, a spring release mechanism, slide release mechanism, mechanical latches, snap-fitting mechanisms, or another type as disclosed herein), a change in magnetic polarity, or another component used to restrain movement of the ear worn device 380. The activation state may include an active state and an inactive state. In some examples, a default of the activation state is the active state when the ear worn device 380 is received by the case 390. In some examples, when the ear worn device 380 is received by the case 390 and the release 382 is an electromagnet, the release 382 is active such that the magnet 394 and the release 382 are magnetically attracted to the other. The user may provide the input to the user input device 392 to alter the activation state. In response, the ear worn device 380 may change the activation state from the active state to the inactive state. The inactive state may deactivate the release 382. In this manner, when the ear worn device 380 is received by the case 390, the release 382 is inactive such that the magnet 394 and the release 382 have reduced magnetic attraction to the other. The user may be able to remove the ear worn device 380 from the case 390 without having to grip and pull the ear worn device 380 to overcome a magnetic attraction. In some examples, the ear worn device 380 remains in the case 390 and the user may provide a reactivation input to the user input device 392 to alter the activation state. In response, the ear worn device 380 may change the activation state from the inactive state to the active state. The active state may activate the release 382 again. In this manner, when the ear worn device 380 is received by the case 390, the release 382 is active such that the magnet 394 and the release 382 are magnetically attracted to the other, as described herein, and the ear worn device 380 remains attached to the case 390. In some instances, the case 390 may receive the reactivation input without having the ear worn device 380 removed from the case 390 or mechanically re-engaging an ejection mechanism.

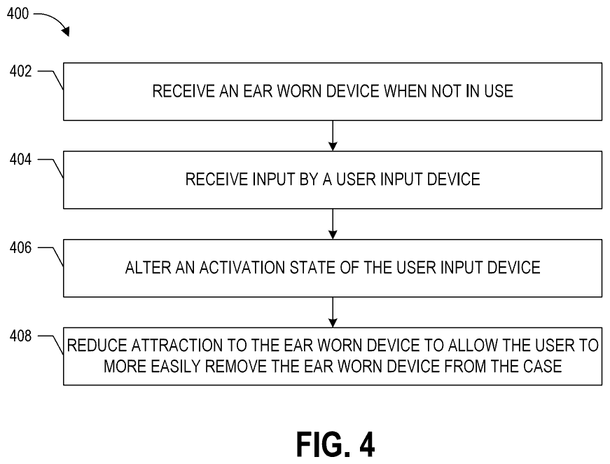

FIG. 4 is one illustrative routine 400 for more easily removing an ear worn device from a case as disclosed herein. The routine 400 may be carried out, for example, by system 200 of FIGS. 2A-2E. The routine 400 begins at block 402, where the system 200 may receive an ear worn device when not in use. In some instances, the system 200 may include the case 210 including a main body 212 and the ear worn device(s) 230, such that the ear worn device(s) 230 may be received by a cavity 214 of the main body 212. In some examples, when the ear worn device(s) 230 is received by the cavity 214, electrical contacts 232 of the ear worn device(s) 230 may interface with corresponding contacts of the case 210. When the ear worn device(s) 230 is received by the case 210, a magnet 236 of the ear worn device(s) 230 may be magnetically attracted to an electromagnet 220 of the case 210. In this manner, the magnetic attraction restrains movement of the ear worn device(s) 230 from the case 210.

At block 404, the system 200 may receive input by a user input device. In some instances, the ear worn device(s) 230 may include a user input device 234 to receive the input. The input may include various types of inputs as disclosed herein. For example, the input may include physical contact between the user (such as a tap of the user's finger) and the user input device 234. In some examples, the case 210 may have a lid 216 in a closed position relative to the main body 212. In this manner, the lid 216 may be adjusted to an open position for the user to access the user input device 234.

At block 406, the system 200 may alter an activation state of the user input device. In some instances, the activation state may change in response to the input from the user. The activation state may change in accordance with the processes disclosed herein. For example, the user input device 234 may be a capacitive switch and the user input may include physical contact, such that the capacitive switch generates an electrical signal. In response to receiving the user input, the ear worn device(s) 230 may generate an instruction to transmit to the case 210 via electrical contacts 232. The case 210 may activate (or deactivate) the electromagnet 220 in response to receiving the instruction.

At block 408, the system 200 may reduce attraction to the ear worn device to allow the user to more easily remove the ear worn device from the case. In some instances, the case 210 may deactivate the electromagnet 220 to reduce the attraction to a magnet 236 of the ear worn device(s) 230. The case 210 may deactivate the electromagnet 220 via operations as disclosed herein. For example, the case 210 may stop generating an electrical signal across a wire to stop producing a magnetic field, such that the electromagnet 220 reduces the magnetic attraction to the magnet 236. In this manner, the user may be able to remove the ear worn device(s) 230 from the case 210 without having to overcome a magnetic attraction.

FIG. 5 illustrates a block diagram 500 of optional features of the ear worn device and/or the case in accordance with aspects of this disclosure. As illustrated in FIG. 5, the block diagram 500 may include features as part of a system(s) 502, such as the ear worn device 100 and/or the case 210. The ear worn device 100 and/or the case 210 may optionally include any or all of processor 504, accelerometer 506, gyroscope 508, other sensor(s) 510, power source 516, microphone(s) 518, storage device 520, communication module 522, speaker(s) 526, and/or vibration motor 530. The processor 504 can be configured, among other things, to process data, execute instructions to perform one or more functions, and/or control the operation of the ear worn device 100 and/or the case 210.

The ear worn device 100 and/or the case 210 can include at least one accelerometer 506. The accelerometer 506 can be, for example, a three-dimensional (3D) accelerometer. The accelerometer 506 may provide acceleration and/or movement data regarding the ear worn device 100 and/or the case 210. In some examples, the ear worn device 100 and/or the case 210 may alter an activation state in response to the acceleration and/or movement data. For example, the activation state may remain in an active state when the accelerometer 506 measures movement by the ear worn device 100 and/or the case 210. In this manner, an electromagnet may be active, such that the ear worn device 100 may be magnetically attracted to the case 210.

The ear worn device 100 and/or the case 210 can include at least one gyroscope 508. The gyroscope 508 may provide orientation data regarding the ear worn device 100 and/or the case 210. In some examples, the ear worn device 100 and/or the case 210 may alter an activation state in response to the orientation data. For example, the activation state change to an inactive state when the gyroscope 508 measures a rotation in orientation to a downward position of the ear worn device 100 and/or the case 210. In this manner, an electromagnet may be inactive, such that the ear worn device 100 may have a reduced magnetic attraction to the case 210.

The ear worn device 100 and/or the case 210 can include at least one IMU for measuring motion, orientation, and/or location of a user 1 (e.g., one or more of a combination of accelerometer 506 and/or gyroscope 508). An IMU can be configured to determine motion, orientation, position and/or location of a user 1. Further, the processor 504 may be configured to receive motion, orientation, position, and/or location data of a user 1 from at least one IMU. Additionally, the processor 504 may determine motion, orientation, position, and/or location of a user 1 based on data received from at least one IMU. For example, the ear worn device 100 and/or the case 210 can include an IMU that can measure static and/or dynamic acceleration forces and/or angular velocity. By measuring static and/or dynamic acceleration forces and/or angular velocity, an IMU can be used to calculate movement and/or relative position of ear worn device 100 and/or the case 210. The IMU can include one or more, and/or a combination of, for example, an AC-response accelerometer (e.g., a charge mode piezoelectric accelerometer and/or a voltage mode piezoelectric accelerometer), a DC-response accelerometer (for example, capacitive accelerometer, piezoresistive accelerometer), a microelectromechanical system (MEMS) gyroscope, a hemispherical resonator gyroscope (HRG), vibrating structure gyroscope (VSG), a dynamically tuned gyroscope (DTG), fiber optic gyroscope (FOG), a ring laser gyroscope (RLG), and the like. An IMU can measure acceleration forces and/or angular velocity forces in one-dimension, two-dimensions, or three-dimensions. With calculated position and movement data, in some examples, an activation state may be adjusted in response to a position or movement by the user. For example, the activation state change to an active state when the IMU measures a position or location of the ear worn device 100 and/or the case 210. In this manner, an electromagnet may be active, such that the ear worn device 100 may be magnetically attracted to the case 210 when the user is at the position or location. In some examples, the position or location may correspond with the user traveling by vehicle. Any number of IMU's can be used to collect sufficient data to determine position and/or movement of the ear worn device 100 and/or the case 210. Further, the ear worn device 100 and/or the case 210 can be configured to determine and/or keep track of steps and/or distance traveled by a user 1 based on data from at least one IMU (e.g., one or more of a combination of accelerometer 506, gyroscope 508).

In some instances, the ear worn device 100 and/or the case 210 can be configured to determine motion of the user, and accordingly, alter the activation state in response to the user's activity. In some examples, the processor 504 can receive motion related data from a motion sensor of the ear worn device 100 and compare such data to one or more thresholds. Such thresholds can be represented by, for example, a measurement of the total acceleration measured by one or more motions sensors of an IMU during some predetermined duration of time. Additionally, a threshold can be represented by less than the total acceleration, for example the user's contribution to the total acceleration (hereinafter the “user's acceleration”) measured by the IMU (for example, ignoring gravitational effects). For example, a threshold can be represented by an IMU sensing that a user's acceleration is less than 0.05 g's for more than 5 seconds, which may indicate that a subject is stationary. Additionally, a threshold can be represented by, for example, a measurement of motion and/or a change in position as measured by an IMU during a duration of time indicating that a subject is stationary. For example, a threshold may be achieved if an IMU measures very little movement for a duration of time (e.g., less than 1.0, 0.1, 0.01, and/or 0.001 meters for 0.1, 1.0, 10, and/or 100 seconds indicating that a subject is stationary). Further, a threshold may be achieved if an IMU measures very little change in relative position (for example, the patient remains in a location, or near a location for a duration of time). Change in relative position can be measured relative to, for example an external device in communication with the processor 504. Further, a threshold can be represented by a value combined with a tolerance, wherein the threshold may be met if motion, as measured by the IMU remains within the tolerance during a duration of time. For example, a threshold may be met if the user's acceleration, as measured by an IMU, is within a tolerance defined as +/−1, 0.1, 0.01, 0.001 and/or 0.0001 g's of 0.1, 0.2, 0.3 g's and/or any other value. The ear worn device 100 and/or the case 210 may alter the activation state according to the user being stationary for a predetermined duration, such as the durations disclosed herein. In this manner, the electromagnet may be active (or inactive) in response to the user's activity.

The ear worn device 100 and/or the case 210 can include one or more other sensors 510. The other sensors 510 can be, for example, a moisture sensor, an impedance sensor, an acoustic/respiration sensor, an actimetry sensor, an EEG sensor, and/or an ECG sensor, among others. In some examples, the other sensors 510 may include security modules for ensuring the user has permission to access the ear worn device 100 and/or the case 210. For example, the other sensors 510 may include an authentication sensor to obtain a fingerprint (or other physiological material) from the user and determine whether the user has appropriate permission to obtain the ear worn device 100.

The ear worn device 100 and/or the case 210 can include a power source 516. The power source 516 may be wired or wireless. In some examples, the power source 516 can be, for example, a battery. In this manner, the battery can be rechargeable or non-rechargeable. The power source 516 can be, for example, a lithium battery. The power source 516 can provide power for the hardware components of described herein. Additionally, or alternatively, ear worn device 100 can be configured to obtain power from a power source 516 that is external to the ear worn device 100 and/or the case 210. For example, the ear worn device 100 can include or can be configured to connect to a cable which can itself connect to an external power source to provide power to the ear worn device 100. In some implementations, ear worn device 100 and/or the case 210 does not include power source 516.

With continued reference to FIG. 5, the ear worn device 100 and/or the case 210 can include various software and/or hardware components to improve hearing of a user 1 and function as a hearing aid. For example, the ear worn device 100 and/or the case 210 can include one or more microphones 518 (such as one, two, three, four, five, or six or more microphones) and/or one or more speakers 526 (such as one, two, three, four, five, or six or more speakers). The one or more microphones 518 can be operably positioned by the ear worn device 100 and/or the case in a variety of locations on the devices. For example, on a surface(s) of the ear worn device 100 that face away from the user 1 (for example, away from the user's ear, face, and/or neck) when the ear worn device 100 is in use (for example, is secured to the user's ear).

The one or more microphones 518 can be configured to process ambient sound, for example, outside the user's 1 ear. In some implementations, the ear worn device 100 and/or the case 210 may be configured to modify one or more characteristics of ambient sound detected by the one or more microphones 518. For example, the ear worn device 100 can be configured to modify one or more frequencies of ambient sound detected by the microphone(s) 518. In some implementations, the one or more microphones 518 can convert detected ambient sound to digital signals for analysis and/or processing. The ear worn device 100 can be configured to increase and/or decrease one or more frequencies associated with sound detected by the one or more microphones 518, and can communicate such modified frequencies to the one or more speakers 526 for outputting to the user 1. This can be significantly advantageous for many persons suffering from hearing impairments who are unable to hear certain frequencies and/or frequency ranges of sound. Any of such above-described frequency modification can be carried out by one or more processors of the ear worn device 100 that can be similar or identical to processor 504. In some implementations, the processor 504 may include a frequency adjustment module that is configured to carry out such above-described frequency modification. Additionally, and/or alternatively, the ear worn device 100 and/or the case 210 can be configured with circuitry to modulate one or more characteristics of ambient sound (e.g., one or more and/or a combination of a high-pass filter, low-pass filter, bandpass filter, and/or amplifier) detected by the one or more microphones.

In some implementations, the ear worn device 100 and/or the case 210 can be configured to determine and output text to other devices based upon the sound detected by the one or more microphones 518. In some cases, the ear worn device 100 and/or the case 210 may be configured to modify one or more characteristics of ambient sound detected by the one or more microphones 518 based upon a hearing profile of a user 1. The ear worn device 100 and/or the case 210 can be configured to store one or more and/or a plurality of hearing profiles (for example, each associated with a particular user 1) in storage device 520 of the ear worn device 100 and/or the case 210. Alternatively, or additionally, the ear worn device 100 and/or the case 210 can be configured to receive one or more hearing profiles from a separate computing device. For example, one or more hardware processors of such separate computing devices can execute an application (e.g., software application, web or mobile application, etc.) that can execute commands to enable the separate computing device to transmit a hearing profile to the ear worn device 100 and/or the case 210 for use by the ear worn device 100 and/or the case 210. In this manner, the commands may instruct the ear worn device 100 and/or the case 210 to employ the hearing profile to carry out modification of one or more characteristics of detected sound for the user 1 (for example, frequency modification).

In some cases, the ear worn device 100 and/or the case 210 may be configured to amplify sound that is detected by the one or more microphones 518 prior to outputting by the one or more speakers 526. In some implementations, the ear worn device 100 and/or the case 210 may include an amplifier configured to amplify sound detected by the one or more microphones 518 and/or amplify one or more signals generated by the one or more microphones 518 based upon detected sound. In some implementations, the processor 504 may be configured to convert sound detected by the one or more microphones 518 into digital signals, for example, before processing and/or before transmission to the speaker(s) 526.

In some implementations, the ear worn device 100 and/or the case 210 may be configured to receive audio signals from a separate device and emit sound (for example, via speakers 526) based on the received audio signals. In such configurations, the ear worn device 100 and/or the case 210 can function as an audio playback device. The ear worn device 100 and/or the case 210 can include various software and/or hardware components to carry out such audio functions. In some cases, the ear worn device 100 and/or the case 210 may be configured to provide noise cancellation to block out ambient sounds when the ear worn device 100 and/or the case 210 is facilitating audio playback.

The ear worn device 100 and/or the case 210 can be configured to operate in various modes. For example, the ear worn device 100 may be configured to operate in a music or audio playback mode where it facilitates emission of audio to the user's 1 ear via speakers 526 based on received audio signals from a separate device. The ear worn device 100 and/or the case 210 can also be capable of operating in a hearing aid mode where it can modify one or more characteristics of ambient sound detected by the one or more microphones 518 as described above. In some cases, the ear worn device 100 and/or the case 210 can be configured to operate in only one of such modes and/or be ca configured to switch between these modes. The ear worn device 100 and/or the case 210 can be configured to communicate (for example wirelessly communicate) with other devices, such as a mobile phone. In some implementations, the ear worn device 100 and/or the case 210 is configured for communication with a separate computing device (for example, mobile phone) that is configured to execute an application (e.g., software application, web or mobile application, etc.) that can execute commands to enable the separate computing device to instruct the ear worn device 100 and/or the case 210 to employ one of a plurality of modes of the ear worn device 100 and/or the case 210 (for example, the audio playback mode or the hearing aid mode).

The ear worn device 100 and/or the case 210 can include the storage device 520. The storage device 520 can include one or more memory devices that store data, including without limitation, dynamic and/or static random-access memory (RAM), programmable read-only memory (PROM), erasable programmable read-only memory (EPROM), electrically erasable programmable read-only memory (EEPROM), and the like. In some implementations, the storage device 520 can store information indicative and/or related to one or more users. In some implementations, as discussed further herein, the ear worn device 100 can be configured to store information regarding one or more hearing aid profiles, authentication information, motion profiles, and audio profiles of a user 1, and such information can be stored in storage device 520.

The ear worn device 100 and/or the case 210 can include the communication module 522. The communication module 522 can facilitate communication (via wires and/or wireless connection) between the ear worn device 100 (and/or the case 210) and separate devices, such as separate monitoring and/or mobile devices. For example, the communication module 522 can be configured to allow the ear worn device 100 to wirelessly communicate with other devices, systems, and/or networks over any of a variety of communication protocols. The communication module 522 can be configured to use any of a variety of wireless communication protocols, such as Wi-Fi (802.11x), Bluetooth®, ZigBee®, Z-wave®, cellular telephony, infrared, near-field communications (NFC), RFID, satellite transmission, proprietary protocols, combinations of the same, and the like. The communication module 522 can allow data and/or instructions to be transmitted and/or received to and/or from the ear worn device 100 (and/or the case 210) and separate computing devices. The communication module 522 can be configured to transmit processed and/or unprocessed physiological or other information to a separate computing device, which can include, among others, a patient monitor, a mobile device (for example, an iOS or Android enabled smartphone, tablet, laptop), a desktop computer, a server or other computing or processing device for display and/or further processing. Such separate computing devices can be configured to store and/or further process the received physiological and/or other information, to display information indicative of or derived from the received information, and/or to transmit information—including displays, alarms, alerts, and notifications—to various other types of computing devices and/or systems that may be associated with a hospital, a caregiver (for example, a primary care provider), and/or a user 1 (for example, an employer, a school, friends, family) that have permission to access the user's 1 data. In some examples, the communication module 522 can include a wireless transceiver.

The one or more speakers 526 can be configured to output sound into and/or toward the user's 1 ear. The one or more speakers 526 can be operably positioned by the ear worn device 100 and/or the case 210 in a variety of locations, for example, on a portion or portions of the ear worn device 100 and/or the case 210 that face toward the user 1 when the ear worn device 100 and/or the case 210 is in use. For example, the one or more speakers 526 can be operably positioned by the ear worn device 100 to direct output sound within and/or toward the ear canal of the user 1. In some implementations, the one or more speakers 526 can be positioned on and/or along an ear canal portion of the ear worn device 100 that is positioned within the user's 1 ear canal when the ear worn device 100 and/or the case 210 is in use.

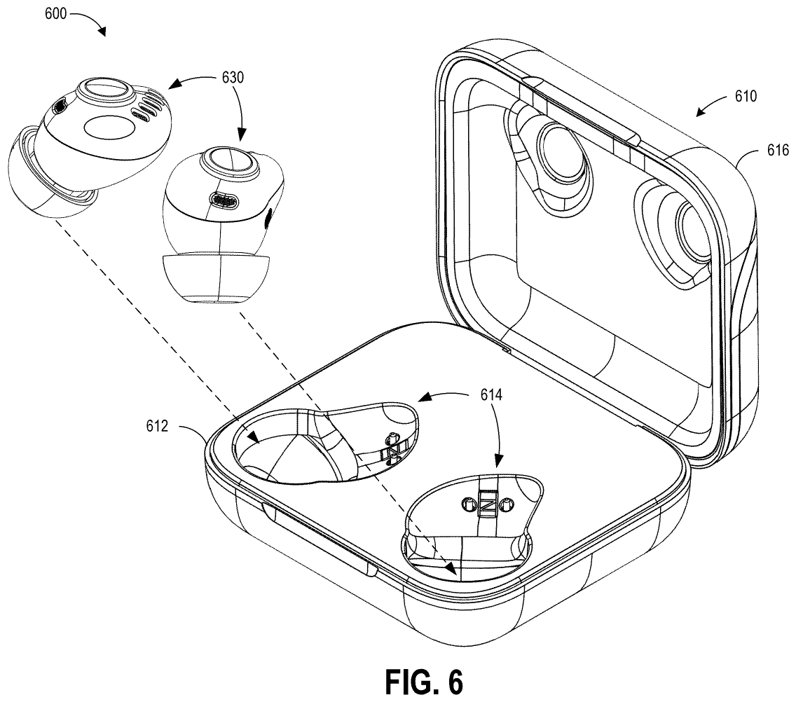

FIG. 6 illustrates a system 600 (may also be referred to as a “kit”) including an ear worn device(s) 630 separated from a case 610 in an open configuration (which may also be referred to as a “state”). The open configuration may include the ear worn device(s) 630 being separated from the case 610 when an electromagnetic connection is deactivated. In this manner, the ear worn device(s) 630 may be removed from the case 610 and provide audio to a user's ear. For example, the user may be listening to music or receiving hearing support via the ear worn device(s) 630. In some instances, the case 610 may receive the ear worn device(s) 630. The case 610 may include a main body 612 (may also be referred to as a base) and a lid 616. The main body 612 and the lid 616 may protect the ear worn device(s) 630 when the ear worn device(s) 630 is restrained within the case 610. In some examples, the main body 612 may include a cavity 614 to receive the ear worn device(s) 630.

In some instances, the case 610 may include a cavity 614. The cavity 614 may include one or more cavities that are configured to receive a portion of the ear worn device(s) 630. For example, the case 610 may include one or two cavities depending on the number of ear worn devices configured to receive. The cavities may be configured to receive and/or secure a portion or portions of the ear worn device(s) 630.

In some instances, the lid 616 may be positioned in an open position or a closed position. The lid 616 may be in the open position to expose a part of main body 612. In this open position, the lid 616 may allow the user to access the ear worn device(s) 630 (removing the device(s) 630 when the device(s) 630 is received by main body 612) or to store the ear worn device(s) 630 (replacing the device(s) 630 in the cavity 614 when the user stops using the device(s) 630). In some examples, the closed position may place the lid 616 over a top of the main body 612. In the closed position, a portion of the lid 616 may contact the main body 612. The contact between the lid 616 and the main body 612 may occur along an entire perimeter length for each of the lid 616 and the main body 612. In this manner, the closed position may enclose a space. In the closed position, the lid 616 and main body 612 may enclose the ear worn device(s) 630 and/or the cavity 614 in the space. In some instances, the lid 616 may be in the open or closed position according to a rotation of the lid 616 with respect to the main body 612 along an axis. The axis may extend along a hinge that interconnects the lid 616 with the main body 612 along the perimeter length for each. The hinge may allow the lid 616 to move relative to main body 612. The rotation along the axis may allow the lid 616 to move from the open position to the closed position (or the closed position to the open position). In the closed position, there is no rotation of the lid 616. The open position may arise in response to the lid 616 rotating from the closed position until the lid 616 reaches a maximum open position. The main body 612 may include a first housing magnet and the lid 616 may include a second housing magnet, each of the housing magnets may be located in a portion of the lid 616 and the main body 612, respectively, opposite of the hinge. When the case 610 is in the closed position the first housing magnet and the second housing magnet may be at a position closest to one another.

The ear worn device(s) 630 may be removable from the case 610 to be positioned in the user's ear. In some instances, the ear worn device(s) 630 may provide audio to the user's ear. The ear worn device(s) 630 may provide audio content to the user and/or enhance hearing capabilities of the user. In some examples, the ear worn device(s) 630 may be one or more earbud, headphone, hearing device (such as a hearing aid), sound suppressing device (such as ear muffs and/or ear plugs), and/or any combination of the foregoing or another ear worn device applicable to the disclosure herein. In some examples, the ear worn device(s) 630 may be difficult for some users to remove from the case 610 due to decreased dexterity capabilities of the user. In some examples, the ear worn device(s) 630 may include electrical contacts, a user input device, and a magnet. As disclosed herein, the user may instruct the electromagnet to reduce magnetic attraction and allow the user to remove the ear worn device(s) 630 from the case 610. In this manner, the ear worn device(s) 630 is removable without the user having to grip the ear worn device(s) 630 and pull the ear worn device(s) 630 from the case 610 to overcome a magnetic attraction, which may be restrictive to some users.

### Terminology

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount. As another example, in certain aspects, the terms “generally parallel” and “substantially parallel” refer to a value, amount, or characteristic that departs from exactly parallel by less than or equal to 10 degrees, 5 degrees, 3 degrees, or 1 degree. As another example, in certain aspects, the terms “generally perpendicular” and “substantially perpendicular” refer to a value, amount, or characteristic that departs from exactly perpendicular by less than or equal to 10 degrees, 5 degrees, 3 degrees, or 1 degree.

Many other variations than those described herein will be apparent from this disclosure. For example, certain acts, events, or functions of any of the algorithms described herein can be performed in a different sequence, can be added, merged, or left out altogether (for example, not all described acts or events are necessary for the practice of the algorithms). Moreover, acts or events can be performed concurrently, for example, through multi-threaded processing, interrupt processing, or multiple processors or processor cores or on other parallel architectures, rather than sequentially. In addition, different tasks or processes can be performed by different machines and/or computing systems that can function together.

It is to be understood that not necessarily all such advantages can be achieved in accordance with any particular example of the examples disclosed herein. Thus, the examples disclosed herein can be embodied or carried out in a manner that achieves or optimizes one advantage or group of advantages as taught herein without necessarily achieving other advantages as may be taught or suggested herein.

The various illustrative logical blocks, modules, and algorithm steps described in connection with the examples disclosed herein can be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described in connection with the examples disclosed herein can be implemented or performed by a machine, such as a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor can be a microprocessor, but in the alternative, the processor can be a controller, microcontroller, or state machine, combinations of the same, or the like. A processor can include electrical circuitry or digital logic circuitry configured to process computer-executable instructions. In another example, a processor can include an FPGA or other programmable device that performs logic operations without processing computer-executable instructions. A processor can also be implemented as a combination of computing devices, for example, a combination of a DSP and a microprocessor, a plurality of microprocessors, one or more microprocessors in conjunction with a DSP core, or any other such configuration. A computing environment can include any type of computer system, including, but not limited to, a computer system based on a microprocessor, a mainframe computer, a digital signal processor, a portable computing device, a device controller, or a computational engine within an appliance, to name a few.

The steps of a method, process, or algorithm described in connection with the examples disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile. The processor and the storage medium can reside in an ASIC.

The apparatuses and methods described herein may be implemented by one or more computer programs executed by one or more processors. The computer programs include processor-executable instructions that are stored on a non-transitory tangible computer readable medium. The computer programs may also include stored data. Non-limiting examples of the non-transitory tangible computer readable medium are nonvolatile memory, magnetic storage, and optical storage.

The term “substantially” when used in conjunction with the term “real-time” forms a phrase that will be readily understood by a person of ordinary skill in the art. For example, it is readily understood that such language will include speeds in which no or little delay occurs.

Conditional language used herein, such as, among others, “can,” “might,” “may,” “for example,” and the like, unless specifically stated otherwise, or otherwise understood within the context as used, is generally intended to convey that certain examples include, while other examples do not include, certain features, elements and/or states. Thus, such conditional language is not generally intended to imply that features, elements and/or states are in any way required for one or more examples or that one or more examples necessarily include logic for deciding, with or without author input or prompting, whether these features, elements and/or states are included or are to be performed in any particular example. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. Further, the term “each,” as used herein, in addition to having its ordinary meaning, can mean any subset of a set of elements to which the term “each” is applied.

Disjunctive language such as the phrase “at least one of X, Y, or Z,” unless specifically stated otherwise, is otherwise understood with the context as used in general to present that an item, term, etc., may be either X, Y, or Z, or any combination thereof (for example, X, Y, and/or Z). Thus, such disjunctive language is not generally intended to, and should not, imply that certain examples require at least one of X, at least one of Y, or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C. Unless otherwise explicitly stated, the terms “set” and “collection” should generally be interpreted to include one or more described items throughout this application. Accordingly, phrases such as “a set of devices configured to” or “a collection of devices configured to” are intended to include one or more recited devices. Such one or more recited devices can also be collectively configured to carry out the stated recitations. For example, “a set of servers configured to carry out recitations A, B and C” can include a first server configured to carry out recitation A working in conjunction with a second server configured to carry out recitations B and C.

While the above detailed description has shown, described, and pointed out novel features as applied to various examples, it will be understood that various omissions, substitutions, and changes in the form and details of the devices or algorithms illustrated can be made without departing from the spirit of the disclosure. As will be recognized, the inventions described herein can be embodied within a form that does not provide all of the features and benefits set forth herein, as some features can be used or practiced separately from others.

Additionally, all publications, patents, and patent applications mentioned in this specification are herein incorporated by reference to the same extent as if each individual publication, patent, or patent application was specifically and individually indicated to be incorporated by reference.

What is claimed is:

1. A system, comprising:
an ear worn device configured to provide audio to an ear of a user;
a switch configured to receive physical contact from the user and, in response, alter an activation state of the switch; and
a case configured to receive the ear worn device when not in use, wherein the case comprises an electromagnet configured to magnetically attract the ear worn device, wherein changing the activation state of the switch causes the electromagnet to reduce attraction to the ear worn device to allow the user to more easily remove the ear worn device from the case.

2. The system of claim 1, wherein the switch is one of: a capacitive switch, a mechanical switch, or an inductive switch.

3. The system of claim 1, wherein either the ear worn device comprises the switch or the case comprises the switch.

4. The system of claim 1, wherein the ear worn device comprises a magnet configured to magnetically attract to the electromagnet according to the activation state.

5. The system of claim 4, wherein the ear worn device further comprises:
an exterior surface, wherein the switch is positioned along the exterior surface; and
an interior volume, wherein the magnet is positioned within the interior volume.

6. The system of claim 1, wherein the case further comprises a lid and a main body configured to protect the ear worn device when the ear worn device is restrained within the lid and the main body of the case, wherein the lid is hingedly coupled to the main body, wherein a movement by the lid about an axis results in an open position or a closed position of the case.

7. The system of claim 5, wherein the main body comprises the electromagnet and a cavity to receive the ear worn device, wherein the main body comprises a first housing magnet and the lid comprises a second housing magnet, wherein the case is in the closed position when a movement by the lid about the axis results in the first housing magnet and the second housing magnet being in a closed position.

8. The system of claim 1, wherein the ear worn device is at least one earbud for the user to listen to audio content or the ear worn device is at least one hearing device to enhance hearing capabilities of the user.

9. A system, comprising:
an ear worn device configured to receive physical contact from a user, wherein the ear worn device comprises:
a capacitive switch configured to receive the physical contact from the user and, in response, alter an activation state of the capacitive switch; and
a magnet configured to adjust movement of the ear worn device by magnetic coupling in response to the activation state of the capacitive switch; and
a case configured to operably couple with the ear worn device, wherein the case comprises an electromagnet configured to adjust magnetic attraction to the magnet according to the activation state, wherein changing the activation state of the capacitive switch changes the magnetic attraction of the electromagnet.

10. The system of claim 9, wherein the case further comprises a lid and a main body configured to protect the ear worn device when the ear worn device is restrained within the lid and the main body of the case, wherein the lid is hingedly coupled to the main body, wherein a movement by the lid about an axis results in an open position or a closed position of the case.

11. The system of claim 10, wherein the main body comprises:
the electromagnet;
a cavity to receive the ear worn device; and
a first housing magnet, and
wherein the lid comprises a second housing magnet,
wherein the case is in the closed position when a movement by the lid about the axis results in the first housing magnet and the second housing magnet being in a closed position.

12. The system of claim 9, wherein when the ear worn device is restrained by the magnet and the electromagnet, the electromagnet is magnetically coupled with the magnet and the activation state is in an active state.

13. The system of claim 9, wherein when the ear worn device is released by the magnet and the electromagnet, the electromagnet is magnetically decoupled with the magnet and the activation state is in an inactive state.

14. The system of claim 9, wherein the ear worn device further comprises:
an exterior surface, wherein the capacitive switch is positioned along the exterior surface; and
an interior volume, wherein the magnet is positioned within the interior volume.

15. The system of claim 9, wherein the ear worn device is at least one earbud for the user to listen to audio content or at least one hearing device to enhance hearing capabilities of the user.

16. A system, comprising:
a case configured to receive physical contact from a user, wherein the case comprises:
a capacitive switch configured to receive the physical contact from the user and, in response, alter an activation state of the capacitive switch; and
an electromagnet coupled to the capacitive switch and configured to adjust magnetic attraction according to the activation state of the capacitive switch, wherein changing the activation state of the capacitive switch changes the magnetic attraction of the electromagnet; and
an ear worn device configured to operably couple with the ear worn device, wherein the ear worn device comprises a magnet configured to adjust movement of the ear worn device by magnetic coupling with the electromagnet according to the activation state.

17. The system of claim 16, wherein the case further comprises a lid and a main body configured to protect the ear worn device when the ear worn device is restrained within the lid and the main body of the case, wherein the lid is hingedly coupled to the main body, wherein a movement by the lid about an axis results in an open position or a closed position of the case.

18. The system of claim 17, wherein the main body comprises:
the electromagnet;
a cavity to receive the ear worn device; and
a first housing magnet,
wherein the lid comprises a second housing magnet,
wherein the case is in the closed position when a movement by the lid about a hinge axis results in the first housing magnet and the second housing magnet being in a closest position.

19. The system of claim 16, wherein in response to the ear worn device being restrained by the magnet and the electromagnet, the electromagnet is magnetically coupled with the magnet and the activation state is in an active state, and in response to the ear worn device being released by the magnet and the electromagnet, the electromagnet is magnetically decoupled with the magnet and the activation state is in an inactive state.

20. The system of claim 16, wherein the case further comprises an exterior surface, wherein the capacitive switch is positioned along the exterior surface, and wherein the ear worn device further comprises an interior volume, wherein the electromagnet is positioned within the interior volume.
